(19) United States
(12) Patent Application Publication
(10) Pub. No.: US 2024/0070338 A1
(43) Pub. Date: Feb. 29, 2024

(54) APPARATUSES, COMPUTER-IMPLEMENTED METHODS, AND COMPUTER PROGRAM PRODUCTS FOR MODELING ENVIRONMENT-RELATED DATA FROM REAL-TIME DATA ALERTS

(71) Applicant: Honeywell International Inc., Charlotte, NC (US)

(72) Inventors: Rahul Jaikaran CHILLAR, Marietta, GA (US); Manyphay Viengkham, Cumming, GA (US); Usman Khawaja Shuja, Atlanta, GA (US)

(21) Appl. No.: 17/897,941

(22) Filed: Aug. 29, 2022

(51) Int. Cl. G06F 30/13

(52) U.S. Cl. CPC G06F 30/13

(57) ABSTRACT

Embodiments of the present disclosure receive and process various monitored data, including real-time monitored data and/or non-real-time monitored data, to generate alert impact data associated with one or more environments. Some embodiments receive, at least one alert associated with operation of an environment, the at least one alert determined based at least in part on real-time monitored data captured via at least one system in the environment; apply the at least one alert to a model that determines alert impact data based at least in part on the at least one alert; determine environment value data based at least in part on the alert impact data; and output at least the environment value data.

### TECHNICAL FIELD

Embodiments of the present disclosure generally are directed to performing accurate data modeling, and specifically to modeling environment-related data utilizing data alert(s) and associated information as limited data inputs.

### BACKGROUND

Information management regarding an environment, operational aspects thereof, and/or related determinations is often attempted via any number of systems, processes, and/or users. In this regard, such information management often is segmented in a manner that requires external integration of these disparate systems, processes, and/or users to aggregate or make determinations regarding the totality of data associated with a particular environment. Further still, in circumstances where aggregation of such data is centralized, such aggregation often only provides insight at a particular time (and that can readily become outdated), is relevant to current owners and/or operators of an environment, and otherwise may not represent a transparent, up-to-date insight with respect to the particular environment.

Applicant has discovered problems with current implementations for managing data associated with an environment and deriving data therefrom. Through applied effort, ingenuity, and innovation, Applicant has solved many of these identified problems by developing embodied in the present disclosure, which are described in detail below.

### BRIEF SUMMARY

The appended claims provide a brief summary of the disclosure.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an example system in which embodiments of the present disclosure may operate in accordance with at least some embodiments of the present disclosure.

FIG. 2 illustrates a block diagram of an example apparatus in accordance with at least some embodiments of the present disclosure.

FIG. 3 illustrates an example data flow in an example computing environment in accordance with at least some embodiments of the present disclosure.

FIG. 4 illustrates an example data flow for deriving data insight(s) for a particular environment and outputting corresponding data to one or more view(s) in accordance with at least some embodiments of the present disclosure.

FIG. 5 illustrates an example data flow for deriving portfolio-level data insight(s) for a particular plurality of environments in accordance with at least some embodiments of the present disclosure.

FIG. 6 illustrates an example data flow for environment value data generation in accordance with at least some embodiments of the present disclosure.

FIG. 7 illustrates an example data flow for environment improvement recommendation determination in accordance with at least some embodiments of the present disclosure.

FIG. 8 illustrates an example process 800 for alert impact data modeling and use in accordance with at least some embodiments of the present disclosure.

FIG. 9 illustrates an example process 900 for determining alert impact data for at least one alert in accordance with at least some embodiments of the present disclosure.

FIG. 10 illustrates an example process 1000 for identifying and outputting an environment improvement recommendation sufficiently contributing to alert impact data in accordance with at least some embodiments of the present disclosure.

FIG. 11 illustrates an example process 1100 for identifying and outputting an environment improvement recommendation to satisfy a target improvement rate in accordance with at least some embodiments of the present disclosure.

FIG. 12 illustrates an example process 1200 for deriving and outputting scores for at least one metric in accordance with at least some embodiments of the present disclosure.

FIG. 13 illustrates an example process 1300 for tracking and outputting a timeseries of data records in accordance with at least some embodiments of the present disclosure.

FIG. 14 illustrates an example process 1400 for determining and outputting an environment improvement recommendation for improving total alert impact data for an environment portfolio in accordance with at least some embodiments of the present disclosure.

FIG. 15 illustrates an example process 1500 for determining and outputting a remaining useful lifetime of a system impacting operational aspect(s) of an environment in accordance with at least some embodiments of the present disclosure.

FIG. 16 illustrates an example user interface associated with cybersecurity data insights in accordance with at least some embodiments of the present disclosure.

FIG. 17 illustrates an example user interface associated with operations & maintenance data insights in accordance with at least some embodiments of the present disclosure.

FIG. 18 illustrates an example user interface associated with sustainability data insights in accordance with at least some embodiments of the present disclosure.

FIG. 19 illustrates an example user interface associated with energy performance data insights in accordance with at least some embodiments of the present disclosure.

FIG. 20 illustrates an example user interface associated with portfolio-level data insights for a plurality of different types of data insights in accordance with at least some embodiments of the present disclosure.

FIG. 21 illustrates an example sub-interface depicting portfolio utilization based on visitor count in accordance with at least some embodiments of the present disclosure.

FIG. 22 illustrates an example user interface associated with portfolio-level data insight adjustable based on predicted data impacts of proposed recommendations in accordance with at least some embodiments of the present disclosure.

FIG. 23 illustrates an example user interface associated with portfolio-level data insights after adjustment based on predicted data impacts of proposed recommendations in accordance with at least some embodiments of the present disclosure.

FIG. 24 illustrates an example sub-interface depicting a summary of predicted data impacts of proposed recommendations in accordance with at least some embodiments of the present disclosure.

### DETAILED DESCRIPTION

Embodiments of the present disclosure now will be described more fully hereinafter with reference to the accompanying drawings, in which some, but not all, embodiments of the disclosure are shown. Indeed, embodiments of the disclosure may be embodied in many different forms and should not be construed as limited to the embodiments set forth herein, rather, these embodiments are provided so that this disclosure will satisfy applicable legal requirements. Like numbers refer to like elements throughout.

### Overview

Various implementation(s) that attempt to manage and/or utilize data associated with environment(s) suffer from various deficiencies. Often such implementation(s) fail to provide a centralized point of truth for data regarding operational aspects of an environment, increased continuity as environment owner or association is transferred between entities, increased data transparency with regard to risk of impact on metrics and/or values associated with the environment, and/or real-time updates to data insights with respect to one or more environment(s). Additionally, such implementations are unable to accurately perform particular determination(s) and/or derivation(s) regarding particular data values, for example whether degradation or deferred maintenance of one or more aspect(s) of an environment impact value of the environment. Some attempted implementations lack sufficient congruency and/or completeness of such data maintenance to enable accurate generation determination(s) to be made based on such data, for example triggering of alert(s) and/or usage thereof.

Embodiments of the present disclosure provide a centralized and dynamically updatable system for maintaining and/or utilizing monitored data. Additionally or alternatively, some embodiments accurately improve alert impact data generation, including at least in part on circumstances where additional and/or specific data associated with alert impact data is not available to the embodiment. In this regard, such embodiments provide an advantageous methodology even in circumstances where conventional data is unavailable for such purposes. Additionally or alternatively, some embodiments enable different views of data and/or derivations thereof, enabling customization of what data elements a user sees based on a view type associated with particular functionality. In the context of building ownership lifecycle for example, embodiments of the present disclosure provide access to different views at each stage throughout the lifecycle (e.g., a first view that includes data relevant to a potential acquirer of an environment, a second view that includes data relevant to a maintainer of an acquired environment, and a third view relevant to a divester of an environment).

### Definitions

“Alert” refers to electronically managed data indicating a particular threshold has been satisfied, a data-driven trigger has been triggered, and/or a tracked data-driven determination result.

“Alert criticality level” refers to electronically managed data indicating a significance level of an alert in a range of candidate significances.

“Alert impact data” refers to electronically managed data representing a data value that impacts or offsets another data value. In one example context, alert impact data represents a value of deferred maintenance associated with an environment.

“Alert importance data” refers to electronically managed data that impacts an importance of an alert. Non-limiting examples of alert importance data include an alert type, a system type corresponding to the alert, alert criticality level corresponding to the alert, and/or location data associated with an environment corresponding to the alert.

“Alert type” refers to electronically managed data indicating what data-driven determination lead to an alert. In one non-limiting example context, a first alert type indicates a particular threshold has been satisfied, a second alert type indicates a data-driven trigger has been triggered, and a third alert type indicates a tracked data-driven determination result was reached.

“Constrained resource value” refers to electronically managed data representing a value for particular resource to be utilized in a determination, where the determination cannot be performed in a manner that exceeds the value. Non-limiting examples of a constrained resource value, for example in the context of determining an environment improvement recommendation, include an available amount of funds, an available length of time, available human resources, and/or a combination thereof.

“Data insight” refers to any data-driven determination, score, or other value derived or otherwise determined based at least in part on monitored data for a particular environment. In some embodiments, a data insight includes a determination of a score for a metric associated with an environment. “Metric” refers to any dynamic attribute or operational aspect of an environment that is trackable for which data may be collected and processed to determine a corresponding level of meeting a desired outcome with respect to the attribute or operational aspect of the environment. Non-limiting examples of a metric include an energy performance metric, a sustainability metric, a cybersecurity risk metric, and a value impact metric (e.g., a deferred maintenance metric).

“Environment” refers to any defined physical area about which monitored data is collected. Non-limiting examples of an environment include a residential building, an office building, a manufacturing plant, a pharmaceutical manufacturing plant, a warehouse, a store, and an outside defined space.

“Environment improvement recommendation” refers to electronically managed data identifying a maintenance, replacement, or other action to be performed to improve a data value associated with a data insight, the improvement defined by progression towards a desired value or improvement in a particular direction. Non-limiting examples of an environment improvement recommendation include maintenance of a particular system, replacing a particular system, installing a particular system, and reconfiguring a system.

“Environment portfolio” refers to a plurality of environments linked together by one or more data identifiers. “Portfolio identifier” refers to the electronically managed data that links a plurality of environments to define an environment portfolio.

“Environment value data” refers to electronically managed data that represents a valuation of a particular environment.

“Model” refers to an algorithmic, statistical, artificial intelligence, and/or machine learning model that is specially configured to perform a particular data transformation and/or prediction task.

“Monitored data” refers to any electronically managed data that is collected associated with a particular environment. Non-limiting examples of monitored data includes at least non-real-time monitored data and real-time monitored data.

“Non-real-time monitored data” refers to electronically managed data collected by one or more devices via an offline process, and/or electronically managed data collected and stored then subsequently transmitted to another system for processing at a later timestamp.

“Notification” refers to any data that causes a visual and/or audio output at a computing device. Non-limiting examples of a notification include a data transmission that causes a popup, a data transmission that causes rendering of a user interface within a native software application, a web page, a text message, an email message, and/or a push notification.

“Real-time monitored data” refers to electronically managed data collected in real-time as operations occur within an environment via one or more sensor(s), system(s), and/or other computing device(s) operating in or otherwise monitoring one or more operational aspects of the environment.

“Remaining useful lifetime value” refers to electronically managed data representing a length of time until an environment becomes unusable due to one or more failed capacities, system failures, or other aspects preventing operation within the environment. When used with respect to a particular system, a remaining useful lifetime value refers to a time until failure of one or more component(s) of the system renders the system unusable or unreliable.

“Target improvement rate” refers to electronically managed data indicating a desired rate of improvement in one or more data values over a particular timestamp interval.

“Timeseries of data records” refers to a plurality of data objects indicating a data value over a particular interval of timestamps. A timeseries of data records may be collected continuously over a particular timestamp interval or at particular intervals (e.g., every minute, hourly, or another time interval).

“Total alert impact data” refers to electronically managed data representing an aggregation of a plurality of alert impact data for a plurality of environments. In one example context, total alert impact data represents the aggregation of alert impact data for all environments in an environment portfolio.

“View type” refers to electronically managed data representing a manner in which one or more portion(s) of data is to be displayed. In some embodiments, a view type corresponds to a user account type and/or a request by a user to access data via a particular view.

### Example Systems and Apparatuses of the Disclosure

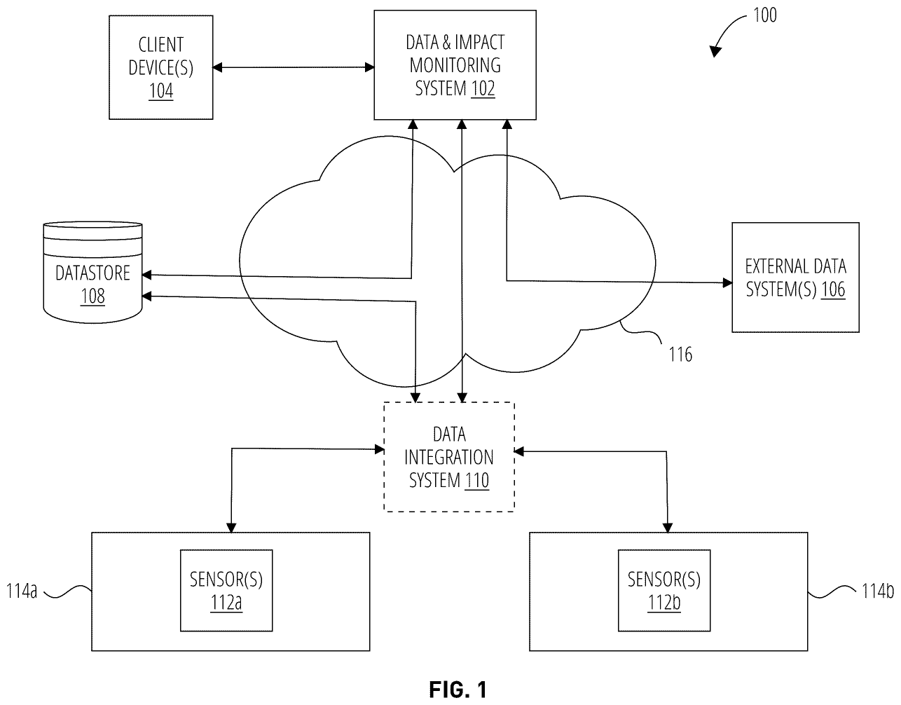

FIG. 1 illustrates an example system in which embodiments of the present disclosure may operate in accordance with at least some embodiments of the present disclosure. Specifically, FIG. 1 depicts an example system 100. The example system 100 includes data & impact monitoring system 102, client device(s) 104, external data system(s) 106, datastore 108, data integration system 110, and sensor(s) 112a and sensor(s) 112b located in environment 114a and environment 114b, respectively. One or more client device(s), such as the client device(s) 104, data & impact monitoring system 102, external data system(s) 106, datastore 108, data integration system 110, and/or sensor(s) 112a and sensor(s) 112b, are each communicable with one or more other communication channels, for example embodied by the communications network 116. It should be appreciated that, in at least some embodiments, one or more component(s) of the system 100 is/are optional. For example, in some embodiments, one or more optional component(s) is not included in the system 100. For purposes of illustration, optional components are depicted utilizing dashed (or “broken”) lines.

As illustrated, the system 100 includes a plurality of environments 114a and environment 114b. Each environment may be configured for any of a myriad of operational actions, for example such that user(s) and/or machinery operates within the environment. Non-limiting examples of such operational actions include user residential actions (e.g., where the environment is an apartment building for example), user commercial actions (e.g., where the environment is an office building for example), warehousing actions (e.g., where the environment is a warehouse for example), manufacturing actions (e.g., where the environment is a pharmaceutical laboratory or manufacturing plant for example), and/or the like. Within each environment, one or more sensor(s) may be positioned that affect or otherwise operate within the environment, for example to provide particular access or other functionality within the environment, activate or otherwise control one or more systems in the environment, and/or the like. Specifically, the system 100 includes a first environment 114a with sensor(s) 112a therein and a second environment 114b with sensor(s) 112b therein.

It will be appreciated that each environment may be monitored independently. For example, sensor(s) 112a may be configured to enable collection of monitored data (e.g., real-time monitored data or non-real-time monitored data) associated with the corresponding environment 114a, and sensor(s) 112b may be configured to enable collection of monitored data associated with the corresponding environment 114b. Such collected data may be stored accordingly, for example in accordance with an environment identifier that uniquely identifies the corresponding environment for particular captured and/or collected data. In some embodiments, the sensor(s) 112a and/or 112b collect raw data that is interpreted by the sensor and/or a corresponding system to generate corresponding monitored data for collection and/or further processing as described herein.

The monitored data associated with each environment, for example via sensor(s) in/associated with the environment and/or external computing systems, is communicated to one or more of the other computing devices and/or stored by one or more other computing devices. For example, in some embodiments, each of the sensor(s) 112a and sensor(s) 112b communicate monitored data to the data & impact monitoring system 102 for processing. In this regard, in some such embodiments the monitored data is transmitted from each of the sensor(s) 112a and/or sensor(s) 112b directly or indirectly to the data & impact monitoring system 102. In some embodiments, the sensor(s) 112a and/or sensor(s) 112b each transmit monitored data to the data & impact monitoring system 102. Alternatively or additionally, in some embodiments the sensor(s) 112a and/or sensor(s) 112b each transmit monitored data via the data integration system 110 and/or to the datastore 108.

The data integration system 110 in some embodiments comprises one or more computing devices embodied in hardware, software, firmware, and/or a combination thereof, that aggregates monitored data for any number of environments, such as the environment 114a and environment 114b. In some embodiments, the data integration system 110 stores such monitored data and/or preprocesses the collected monitored data for further transmittal, storage, and/or use. Additionally or alternatively, in some embodiments, the data integration system 110 is positioned within one or more of the environments, such as the environment 114a and/or environment 114b. Alternatively or additionally, in other embodiments, the data integration system 110 is positioned remote from each of the environments 114a and 114b, for example in a separate, centralized environment for monitoring the various embodiments. In yet other embodiments, the data integration system 110 comprises one or more sub-interfaces within and/or proximate to each of the environments 114a and/or 114b. For example, in an example context where one such environment represents a particular building or a portion of a building, a particular sub-interface of the data integration system 110 includes one or more computing devices embodied in hardware, software, firmware, and/or a combination thereof, that is positioned within a data warehouse and/or office portion of or associated with the environment. In this regard, each of the sub-interfaces alone and/or in combination embody the data integration system 110 operating in conjunction. In some embodiments, a single data integration system 110 is located in a cloud environment with respect to one or more of the environments from which it receives data.

In yet some other embodiments, the sensors such as sensor(s) 112a and/or sensor(s) 112b provide monitored data for storage in the datastore 108. For example, in some embodiments, each of the sensor(s) 112a and/or sensor(s) 112b provide monitored data directly to the datastore 108. In other embodiments, the monitored data is provided indirectly through the data integration system 110 and/or the data & impact monitoring system 102. The datastore 108 may store the monitored data and/or information derived therefrom alone and/or stored together with data identifying the environment associated with said monitored data (e.g., from which it was collected, or otherwise with which it is associated based on one or more identifier(s)). In some embodiments, the datastore 108 is positioned at a same location or proximate to the data & impact monitoring system 102, and/or is embodied by a cloud datastore remote from the data & impact monitoring system 102, environments 114a and/or 114b, and/or data integration system 110. Alternatively or additionally, in some embodiments, the datastore 108 is embodied by a plurality of sub-datastores, for example a datastore associated with each of the environments.

In some embodiments, the data & impact monitoring system 102 receives monitored data in real-time for one or more environments, such as the environment 114a and/or environment 114b. In some such embodiments, the data & impact monitoring system 102 processes the monitored data for any of a myriad of purposes, for example to generate one or more data insights, alerts based on such data, determinations of impact value or other derived data, and/or the like. In some embodiments, additionally or alternatively, the data & impact monitoring system 102 stores a historical record of monitored data in one or more datastores for subsequent processing. For example, in some embodiments, the data & impact monitoring system 102 stores a historical record embodying captured monitored data together with a timestamp indicating a datetime at which the monitored data was captured or otherwise with which the data is associated (e.g., a user-indicated datetime). In some embodiments, such historical records are stored in the data & impact monitoring system 102 alone, and/or in other embodiments are stored to the datastore 108. In some embodiments, the stored historical records of monitored data are retrieved at a subsequent time for purposes of further processing, for example after capture of real-time data, or can be performed as such data is received (e.g., in real-time). The monitored data may represent objective data values associated with the operational aspects of an environment.

In some embodiments, the data & impact monitoring system 102 is configured to process external and/or third-party monitored data not collected via sensor(s) within an environment. For example, in some embodiments, the data & impact monitoring system 102 communicates with and/or processes data retrieved from one or more external data systems, such as the external data system(s) 106. Each of the external data system(s) 106 may include one or more computing devices embodied in hardware, software, firmware, and/or a combination thereof, that collects, aggregates, and/or stores such third-party monitored data for processing. Such third-party monitored data stored by one or more of the external data system(s) 106 may include survey data associated with each of the environments 114a and/or 114b, industry data associated with environments of various environment types, and./or the other data relevant to analyzing the operational health and/or financial health of an environment. In some embodiments, one or more of the external data system(s) 106 is/are controlled, owned, and/or otherwise operated by the same entity than the entity that controls, owns, and/or otherwise operates the data & impact monitoring system 102 and/or the environments 114a and 114b. In other embodiments, one or more of the external data system(s) 106 is/are controlled, owned, and/or otherwise operated by a different entity than the entity that controls, owns, and/or otherwise operates the data & impact monitoring system 102 and/or the environment 114a and/or environment 114b.

In some embodiments the data & impact monitoring system 102 is configured to process monitored data from one or a plurality of data sources, for example monitored data obtained directly or indirectly from the sensor(s) 112a and/or 112b. For example, in some embodiments, the data & impact monitoring system 102 processes real-time monitored data collected via the sensor(s) 112a and/or sensor(s) 112b, and/or non-real-time monitored data received from the external data system(s) 106 or datastore 108. In some embodiments, the real-time monitored data represents or includes data representing current operational aspects of an environment in real-time, and in some embodiments the non-real-time monitored data represents or includes data representing survey data results or other generalized data entered from an offline source, reported by users, and/or the like, which may be associated with a particular timestamp or interval (e.g., a billing cycle or other defined time interval). Additionally or alternatively, in some embodiments, the data & impact monitoring system 102 configures and/or provides data to cause rendering of notification(s) and/or other user interface(s), such as one or more dashboard(s), associated with collected monitored data, data insights derived therefrom, alert(s), or other information derived therefrom.

The data & impact monitoring system 102 includes one or more components embodied in a cloud environment with respect to each of the environments 114a and/or 114b, and/or the client device(s) 104. For example, in some embodiments, the data & impact monitoring system 102 includes at least one processor and/or at least one memory device positioned in one or more cloud environments. In this regard, in some embodiments, the data & impact monitoring system 102 includes such processor(s) and/or memory device(s) in a remote location from the environment 114a and/or environment 114b, and/or in some embodiments from another, such that the cloud processor(s) and/or cloud memory device(s) are communicable over one or more communication networks. It should be appreciated that, in some embodiments, the devices located in the cloud environment are nevertheless configured to work in conjunction with one another to provide a consistent user experience and/or functionality access. In yet other embodiments, the data & impact monitoring system 102 is positioned in an environment, for example one or more of the environment 114a and/or environment 114b. Alternatively or additionally, in some embodiments, each monitored environment includes a data & impact monitoring system 102.

The client device(s) 104 includes one or more computing devices embodied in hardware, software, firmware, and/or a combination thereof, that enables access to functionality provided by the data & impact monitoring system 102. In some embodiments, the client device(s) 104 comprises a user device under the control of a particular user and/or entity that owns, operates, and/or otherwise desires to analyze aspects of the environment 114a and/or environment 114b. For example, in some embodiments, the client device(s) 104 is embodied by a user's mobile device accessing one or more software applications that provide access to the functionality of the data & impact monitoring system 102 as described herein. In some embodiments, the client device(s) 104 is configured to execute a native software application that provides access to such functionality, for example an “app” installed to the client device(s) 104 and executed by the user. In other embodiments, the client device(s) 104 is configured to execute a web-based software application that provides access to such functionality via a browser application installed and/or executing on the client device(s) 104. It should be appreciated that, in some embodiments, the client device(s) 104 communicates with the data & impact monitoring system 102 over one or more communication networks to enable access to such functionality. For example, in some embodiments, the client device(s) 104 communicates with the data & impact monitoring system 102 via the communications network 116 and/or another communications network to enable transmission of requests to the data & impact monitoring system 102, and/or facilitate receiving of response data from the data & impact monitoring system 102, to facilitate access to such functionality.

In some embodiments, the client device(s) 104 communicates with the data & impact monitoring system 102 to establish an authenticated session that enables access to various functionality associated with the data & impact monitoring system 102. For example, in some embodiments, the client device(s) 104 establishes an authenticated session with the data & impact monitoring system 102 to access particular data insights, functionality, and/or raw data values of monitored data associated with the particular environments 114a and/or 114b. In some embodiments, for example, a user utilizes client device(s) 104 to provide user authentication credentials linked to a particular user account maintained by the data & impact monitoring system 102. In this regard, in some embodiments, the user of the client device(s) 104 authenticates a particular user account (e.g., associated with particular environment(s)) to initiate an authenticated session associated with the particular user account, and thus enabling access to data associated with the particular user account. For example, in a context where environment 114a and environment 114b have been associated with a particular user account, and an authenticated session associated with the particular user account has been established via the client device(s) 104, the user may utilize the client device(s) 104 to access monitored data from the sensor(s) 112a and/or sensor(s) 112b, third-party and/or external data provided by the external data system(s) 106 that are associated with the environment 114a and/or environment 114b, and/or processed data or functionality associated therewith (e.g., data insights, alerts associated with such monitored data, recommendations, portfolio-level data insights, and/or the like). Alternatively, in a context where another environment has been associated with a particular user account, and an authenticated session associated with the particular user account has been established via the client device(s) 104, the user may utilize the client device(s) 104 to access such other monitored data, data insights, alerts, recommendations, and/or the like. In this regard, it should be appreciated that different users (e.g., who authenticate different user accounts associated with different user data objects) may be provided access to different data and/or functionality via the data & impact monitoring system 102, such as by initiating an authenticated session with a particular user account.

In some embodiments, the client device(s) 104 enables access to particular functionality via user interface(s) rendered to the client device(s) 104 via communication with the data & impact monitoring system 102. For example, in some embodiments, the data & impact monitoring system 102 provides access to functionality for visualizing monitored data via one or more dashboard user interface(s), custom interface element(s), and/or the like. Alternatively or additionally, in some embodiments, the data & impact monitoring system 102 provides access to functionality for determining and/or outputting data insight(s) derived from monitored data. Alternatively or additionally, in some embodiments, the data & impact monitoring system 102 provides access to functionality for generating one or more alert(s) from monitored data. Alternatively or additionally, in some embodiments, the data & impact monitoring system 102 provides access to functionality for generating derived data from monitored data and/or alert(s), for example alert impact data, and/or outputting such derived data.

The communications network 116 may embody any of a number of public and/or provide network(s) enabling communication between various computing devices. For example, in some embodiments, the communications network 116 includes and/or is embodied by one or more network access device(s), cell tower(s), base station(s), network base station(s), wired and/or wireless connection tower(s), signal booster(s), signal propagation device(s), and/or the like. Each of the devices and/or systems described with respect to the system 100 may access the communications network 116 utilizing any of a myriad of transmission protocols and/or corresponding communications circuitry enabling transmission of specially configured transmissions based on the transmission protocol. A non-limiting example of the communications network 116 includes the Internet, and/or one or more hybrid networks enabling access to the Internet. It should be appreciated that, in some embodiments, the communications network 116 includes one or more sub-networks that facilitate communications between discrete devices of the system 100. For example, in some embodiments, the communications network 116 includes a sub-network that facilitates communication between the data & impact monitoring system 102 and the external data system(s) 106 and/or datastore 108, and a second sub-network that facilitates communication between the data & impact monitoring system 102 and the data integration system 110 and/or sensor(s) 112a and 112b. Each sub-network in some embodiments includes entirely distinct components. In other embodiments, one or more sub-networks include one or more shared components that facilitate such communications.

The methods, apparatuses, systems, and computer program products of the present disclosure may be embodied by any variety of devices. For example, a method, apparatus, system, and computer program product of an example embodiment may be embodied by a fixed computing device, such as a personal computer, computing server, computing workstation, or a combination thereof. Further, an example embodiment may be embodied by any of a variety of mobile terminals, mobile telephones, smartphones, laptop computers, tablet computers, or any combination of the aforementioned devices.

In some embodiments, the system 100 operates to retrieve, receive, collect, and/or maintain various monitored data associated with one or more environments. In some embodiments, monitored data is collected and maintained corresponding to an environment identifier that uniquely identifies the environment with which such monitored data is associated. Additionally or alternatively, in some embodiments, monitored data may be stored and/or aggregable to a higher-level representing a higher-order classification of the data. For example, in some embodiments, a portion of monitored data is collected and stored associated with a particular zone within an environment. Various portions of data values represented in monitored data associated with different zone identifiers may be aggregated together to generate data insights representing new data values for metrics corresponding to a particular floor (for example). Further, various portions of data values represented in such aggregated data for a particular floor identifier may similarly be aggregated with other floor identifiers to generate data insights representing new data values for metrics corresponding to a particular environment. Such aggregation may continue to reach any desired higher-level derivations. For example, two or more environment identifiers may be associated with a particular portfolio identifier, representing that the two or more environment identifiers correspond to a portfolio of environments. In some such embodiments, data associated with such linked environments is aggregable to derive portfolio-level equivalents of the aggregated data portions.

Aggregation and/or contextualization of independent portions of monitored data can be particularly technically challenging in various contexts. For example, in circumstances where monitored data associated with hundreds, thousands, or even more of environments is collected and maintained, such operations can strain available computing resources (e.g., network, storage, processing, and/or the like) significantly. Additionally, accurately aggregating and/or contextualizing such data may be particularly challenging as well based on the distributed nature of such data, differences in source data types, and/or the like. In some embodiments, monitored data is collected, contextualized, and/or aggregated as described in U.S. patent application Ser. No. 17/546,943 filed Dec. 9, 2021, titled “MANAGEMENT OF A PORTFOLIO OF ASSETS,” the contents of which are each incorporated herein by reference in its entirety.

In some embodiments, monitored data is collected via any combination of a myriad of data source types. For example, in some embodiments, monitored data includes telemetry or sensor data generated by the sensor(s) within the environment, for example embodying one or more meter(s), asset sensor(s), environment condition sensor(s), security sensor(s), cybersecurity risk data (e.g., configuration data, attack data, and/or the like), and/or the like. Additionally or alternatively, in some embodiments, the monitored data includes enterprise business data, for example embodying financial data, inventory data, human resource data, compliance data, capital investment data, operational cost data, and/or the like, from one or more sensor(s) and/or external data system(s). Additionally or alternatively, in some embodiments, the monitored data includes work order management data, for example embodying planned work data, assigned resource data, issue and/or resolution data, asset identifier(s) for planned work data, vendor progress data, and/or the like, from one or more sensor(s) and/or external data system(s). Additionally or alternatively, in some embodiments, the monitored data includes building management data, for example embodying asset alarm data, comfort control setting data, physical system control data, and/or the like, from one or more sensor(s) and/or external data system(s). Additionally or alternatively, in some embodiments, the monitored data includes cyber security data that includes asset or system configuration data, system patch status data, intrusion detection data, threat detection data, attack detection data, update schedule data, and/or the like, from one or more sensor(s) and/or external data system(s). It should be appreciated that the monitored data may include any combination of such data.

It should be appreciated that data associated with a particular environment may be aggregated in any of a myriad of ways. In some embodiments, different types of monitored data is aggregated utilizing different methodologies. For example, in some embodiments, any raw data value of monitored data is aggregable with such monitored data for other environments to generate a higher-level data insight. Some data types are normalized before aggregation, for example to ensure that the aggregation is performed accurately. In some embodiments, energy performance data for example is normalized by region, building type, weather climate, and/or area (e.g., square footage) of an environment to provide an accurate comparison based on characteristics of each particular environment.

In some embodiments, sustainability data is contextualized and/or aggregable to generate a higher-level insight. For example, in some embodiments, energy usage data is converted into a carbon equivalent by using one or more energy conversion algorithm(s), which may be industry standard algorithm(s) or custom algorithm(s) particular to known conversion factors for a particular implementation. The carbon equivalent in some embodiments is subsequently aggregable, for example by region, business line, or at a portfolio-level for all environments associated with a particular portfolio of environments. Such aggregated sustainability data in some contexts provides visibility into the carbon impact of a particular environment compared to others and/or of a portfolio of environments.

In some embodiments, environment value data is generated and/or contextualizable in any of a myriad of manners. In some embodiments, environment value data is generated based at least in part on alert count data, as described herein. Such generation of environment value data may be generated with sufficient accuracy to provide a general indicator of environment and/or portfolio value. In some embodiments, generation of environment value data utilizes work order data associated with an environment, or environments of a portfolio. In this regard, ongoing work orders represented by work order data may be utilized to generate impact data that offsets a particular environment value data that would otherwise be attributable to the environment, or portfolio of environments, without the work order(s).

In some embodiments, cybersecurity risk data is generated and/or contextualizable in any of a myriad of manners. In some embodiments, survey data (e.g., represented by a questionnaire provided to operator(s), owner(s), administrator(s), and/or other entities associated with an environment or portfolio of environments) is provided and scored to generate a cybersecurity risk score based at least in part on subject matter expert designations. In this regard, the subject matter designations may indicate the aspects of an environment's operation that pose a high cybersecurity risk. In some embodiments, the cybersecurity risk score(s) for environment(s) are aggregable utilizing a simple average, a weighted average, a standard deviation, and/or the like to represent a grouped or portfolio-level cybersecurity risk score. In some embodiments, a cybersecurity risk score for a particular environment or portfolio of environments is determinable based on detection of intrusion, attacks, and/or the like, for example received from an intrusion detection system. The intrusion detection system may embody a subsystem of the system 100, or embody an external data system, that aggregates information regarding system security patches, number of intrusions, attacks, or the like, system accessibility parameters, and/or the like to utilize in a cybersecurity scoring algorithm that generates a cybersecurity risk score for the environment or portfolio of environments.

It should be appreciated that any data insight described herein may embody a data value of monitored data itself, a data value derived from monitored data, a higher-level data value generated via aggregation, and/or any combination thereof. Accordingly, any determination and/or display of such a data insight should be understood to include any of such data values.

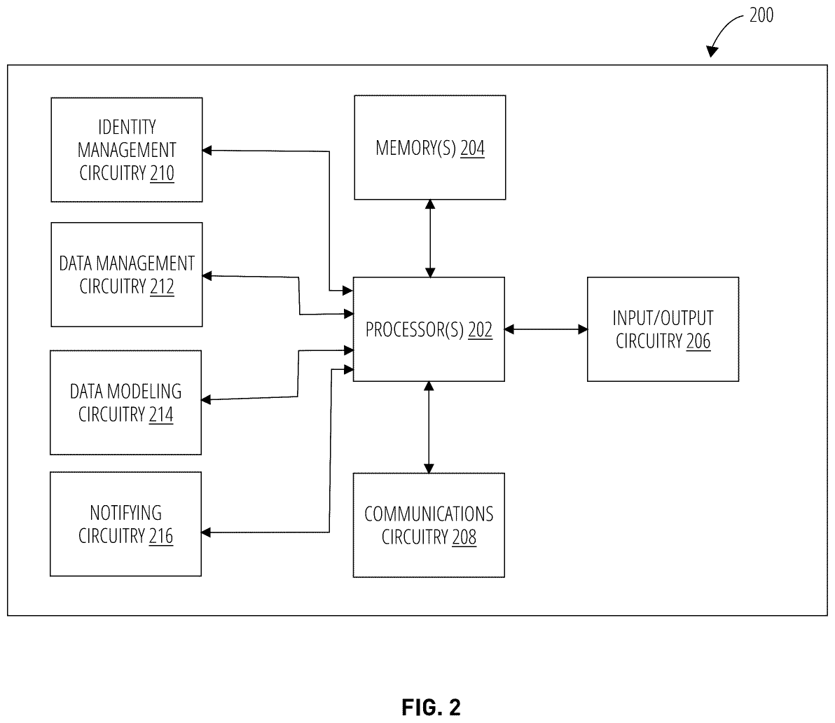

In at least one example embodiment, the data & impact monitoring system 102 is embodied by one or more computing systems, such as the apparatus 200 as shown in FIG. 2. The apparatus 200, as depicted, includes processor(s) 202, memory(s) 204, input/output circuitry 206, communications circuitry 208, identity management circuitry 210, data management circuitry 212, data modeling circuitry 214, and/or notifying circuitry 216. Although the components are described with respect to functional limitations, it should be understood that the particular implementations necessarily include the use of particular hardware. It should also be understood that certain of the components described herein in some embodiments include similar or common hardware. For example, in some embodiments two sets of circuitry both leverage use of the same processor, network interface, storage medium, or the like to perform their associated functions, such that duplicate hardware is not required for each set of circuitry. The use of the term “circuitry” as used herein with respect to components of the apparatus 200 should therefore be understood to include particular hardware configured to perform the functions associated with the particular set of circuitry as described herein.

Additionally or alternatively, the term “circuitry” should be understood broadly to include hardware and, in some embodiments, software and/or firmware for configuring the hardware. For example, in some embodiments, “circuitry” refers to and/or includes processing circuitry, storage media, network interfaces, input/output devices, and the like. In some embodiments, other elements of the apparatus 200 provide or supplement the functionality of the particular circuitry. For example, in some embodiments the processor(s) 202 provide processing functionality, the memory(s) 204 provides storage functionality, the communications circuitry 208 provides network interface functionality, and the like, to one or more of the other sets of circuitry.

In some embodiments, the processor(s) 202 (and/or co-processor or any other processing circuitry assisting or otherwise associated with the processor) is in communication with the memory(s) 204 via a bus for passing information among components of the apparatus. The memory(s) 204 is non-transitory and in some embodiments includes, for example, one or more volatile and/or non-volatile memories. In other words, for example in some embodiments, the memory embodies a non-transitory electronic storage device (e.g., a computer readable storage medium). In some embodiments, the memory 204 is configured to store information, data, content, applications, instructions, or the like, for enabling the apparatus 200 to carry out various functions in accordance with example embodiments of the present disclosure. In some embodiments, for example, the memory(s) 204 embodies one or more databases for storing user data objects, monitored data, derived data values, and/or other data associated therewith, and/or otherwise is configured to maintain such data objects for accessing and/or updating as described herein.

In various embodiments of the present disclosure, the processor(s) 202 is embodied in any one of a myriad of ways and may, for example, include one or more processing devices configured to perform independently. Additionally or alternatively, the processor(s) 202 may include one or more processors configured in tandem via a bus to enable independent execution of instructions, pipelining, and/or multithreading. The use of the terms “processor,” “processing module,” and “processing circuitry” may be understood to include a single-core processor, a multi-core processor, multiple processors internal to the apparatus, other central processing unit (“CPU”), microprocessor, integrated circuit, and/or remote or “cloud” processors.

In an example embodiment, the processor(s) 202 is configured to execute computer-coded instructions stored in the memory(s) 204 or otherwise accessible to the processor. Alternatively, or additionally, in some embodiments, the processor(s) 202 is configured to execute hard-coded functionality. As such, whether configured by hardware or software means, or by a combination thereof, the processor(s) 202 may represent an entity (e.g., physically embodied in circuitry) capable of performing operations according to an embodiment of the present disclosure while configured accordingly. Alternatively or additionally, in another example context, when the processor is embodied as an executor of software instructions, the instructions specifically configure the processor(s) 202 to perform the algorithms and/or operations described herein when the instructions are executed.

As one example context, the processor(s) 202 is configured to support aggregation and/or processing of monitored data for any number of environment(s). In some such embodiments, for example, the processor(s) 202 is configured to receive, retrieve, and/or otherwise collect monitored data from one or more sensor(s) positioned in at least one environment, determine data insight(s) (e.g., score(s) for particular metric(s)) and/or alert(s) based at least in part on monitored data, derive data from the monitored data, data insights, and/or alerts, and/or output data via one or more user interface(s), notification(s), and/or the like. Additionally or alternatively, in some embodiments, the processor(s) 202 is configured to generate environment improvement recommendation(s) for one or more environment.

Additionally or alternatively, in some embodiments, the processor(s) 202 is configured to maintain portfolio-level connections between a plurality of environment(s), and/or process monitored data, alerts, and/or data insights on a portfolio-level. Alternatively or additionally, in some embodiments, the processor(s) 202 is configured to customize data output for one or more view type(s).

In some embodiments, the apparatus 200 includes input/output circuitry 206 that, alone or in communication with processor(s) 202, provides output to the user and/or receives indication(s) of user input. In some embodiments, the input/output circuitry 206 comprises one or more user interfaces, and/or includes a display to which user interface(s) may be rendered. In some embodiments, the input/output circuitry 206 comprises a web user interface, a mobile application, a desktop application, a linked or networked client device, and/or the like. In some embodiments, the input/output circuitry 206 also includes any of a number of peripherals, a keyboard, a mouse, a joystick, a touch screen, touch areas, soft keys, a microphone, a speaker, or other input/output mechanisms. In some such embodiments, the input/output mechanisms are configured to enable a user to provide data representing one or more user interaction(s) for processing by the apparatus 200. The processor and/or input/output circuitry 206 communicable with the processor, for example processor(s) 202, is configured to control one or more functions of one or more user interface elements through computer program instructions (e.g., software and/or firmware) stored on a memory accessible to the processor (e.g., memory(s) 204, and/or the like).

The communications circuitry 208 in embodied by any means such as a device or circuitry embodied in either hardware or a combination of hardware and software that is configured to receive and/or transmit data from/to a network and/or any other device, circuitry, or other module in communication with the apparatus 200. In this regard, the communications circuitry 208 includes, in some embodiments for example, at least a network interface for enabling communications with a wired or wireless communications network. For example, in some embodiments, the communications circuitry 208 includes one or more network interface cards, antennas, buses, switches, routers, modems, and supporting hardware and/or software, or any other device suitable for enabling communications via a network. Additionally or alternatively, the communication interface may include the circuitry for interacting with the antenna(s) to cause transmission of signals via the antenna(s) or to handle receipt of signals received via the antenna(s).

The identity management circuitry 210 include hardware, software, firmware, and/or a combination thereof, configured to support functionality associated with authenticating identity associated with and/or permissioning access for a particular user account. In some embodiments the identity management circuitry 210 utilizes processing circuitry, such as the processor(s) 202, to perform one or more of these actions. In some embodiments, the identity management circuitry 210 includes hardware, software, firmware, and/or a combination thereof, to authenticate user credentials as associated with a user account and initiate an authenticated session associated with the user account. Additionally or alternatively, in some embodiments, the identity management circuitry 210 includes hardware, software, firmware, and/or a combination thereof, to provide access to particular data and/or functionality associated with an authenticated user account. Additionally or alternatively, in some embodiments, the identity management circuitry 210 includes hardware, software, firmware, and/or a combination thereof, to customize output (e.g., a view of data via one or more user interface(s)) based at least in part on a view type or user type. It should be appreciated that, in some embodiments, the identity management circuitry 210 includes or is embodied by a separate processor, specially configured field programmable gate array (FPGA), and/or a specially configured application-specific integrated circuit (ASIC).

The data management circuitry 212 includes hardware, software, firmware, and/or a combination thereof, configured to manage monitored data and/or data derived therefrom. The data management circuitry 212 in some embodiments utilizes processing circuitry, such as the processor(s) 202, to perform one or more of these actions. In some embodiments, the data management circuitry 212 includes hardware, software, firmware, and/or a combination thereof, to collect, request, and/or otherwise receive and/or store monitored data associated with one or more environment(s). Additionally or alternatively, in some embodiments, the data management circuitry 212 includes hardware, software, firmware, and/or a combination thereof, to derive data insight(s) from monitored data associated with one or more environment(s). Additionally or alternatively, in some embodiments, the data management circuitry 212 includes hardware, software, firmware, and/or a combination thereof, to derive data alert(s) based at least in part on monitored data and/or data insight(s). Additionally or alternatively, in some embodiments, the data management circuitry 212 includes hardware, software, firmware, and/or a combination thereof, to process data on a portfolio-level associated with an environment portfolio. It should be appreciated that, in some embodiments, the data management circuitry 212 includes or is embodied by a separate processor, specially configured field programmable gate array (FPGA), and/or a specially configured application-specific integrated circuit (ASIC).

The data modeling circuitry 214 includes hardware, software, firmware, and/or a combination thereof, configured to model derived data based at least in part on received monitored data. The data modeling circuitry 214 in some embodiments utilizes processing circuitry, such as the processor(s) 202, to perform one or more of these actions. In some embodiments, the data modeling circuitry 214 includes hardware, software, firmware, and/or a combination thereof, to apply monitored data, data insight(s), and/or alert(s), to one or more models. For example, in some embodiments, the data modeling circuitry 214 applies monitored data to insight model(s) to generate data insight(s) from monitored data. In some embodiments, the data modeling circuitry 214 applies data alert(s) to one or more alert impact model(s) generate alert impact data from data alert(s). Additionally or alternatively, in some embodiments, the data modeling circuitry 214 includes hardware, software, firmware, and/or a combination thereof, to train one or more data model(s) for use in generating particular data. Additionally or alternatively, in some embodiments, the data modeling circuitry 214 includes hardware, software, firmware, and/or a combination thereof, to determine data impact(s) of recommendation(s) on data insight(s) of one or more metric(s). For example, in some embodiments, the data modeling circuitry 214 includes hardware, software, firmware, and/or a combination thereof, that models predicted data impact(s) for data insight(s) corresponding to particular data metric(s) based at least in part on previous changes to data insight(s) associated with other environment(s) that historically implemented the recommendation and/or changes based at least in part on the recommendation. Additionally or alternatively, in some embodiments, the data modeling circuitry 214 includes hardware, software, firmware, and/or a combination thereof, to generate environment improvement recommendation(s) based at least in part on monitored data, alert(s), and/or data insight(s). It should be appreciated that, in some embodiments, the data modeling circuitry 214 includes or is embodied by a separate processor, specially configured field programmable gate array (FPGA), and/or a specially configured application-specific integrated circuit (ASIC).

The notifying circuitry 216 includes hardware, software, firmware, and/or a combination thereof, configured to generate, manage, and/or otherwise output notification(s), user interface(s) and/or the like. The notifying circuitry 216 in some embodiments utilizes processing circuitry, such as the processor(s) 202, to perform one or more of these actions. In some embodiments, the notifying circuitry 216 includes hardware, software, firmware, and/or a combination thereof, configured to customize configuration of one or more user interface view(s) for outputting to a client device. Additionally or alternatively, in some embodiments, the notifying circuitry 216 includes hardware, software, firmware, and/or a combination thereof, to generate and/or output notification(s) based at least in part on monitored data, data insight(s), and/or alert(s). Additionally or alternatively, in some embodiments, the notifying circuitry 216 includes hardware, software, firmware, and/or a combination thereof, to cause rendering of particular user interface(s). It should be appreciated that, in some embodiments, the notifying circuitry 216 includes or is embodied by a separate processor, specially configured field programmable gate array (FPGA), and/or a specially configured application-specific integrated circuit (ASIC).

In some embodiments, one or more of the aforementioned sets of circuitry are combined to form a single set of circuitry. The single combined set of circuitry may be configured to perform some or all of the functionality described herein with respect to the individual sets of circuitry. For example, in at least one embodiment, the identity management circuitry 210, data management circuitry 212, data modeling circuitry 214, and/or notifying circuitry 216 are embodied by a single set of circuitry, and/or one or more of the identity management circuitry 210, data management circuitry 212, data modeling circuitry 214, and/or notifying circuitry 216 are combined with the processor 202. Additionally or alternatively, in some embodiments, one or more of the sets of circuitry described herein is/are configured to perform one or more of the actions described with respect to one or more of the other sets of circuitry.

### Example Data Flows and Environments of the Disclosure

Having described some example systems and apparatuses in accordance with the present disclosure, example computing environments in accordance with the present disclosure are further described. It should be appreciated that the example computing environments may be maintained by any of the computing devices, apparatuses, systems, and/or the like as described. For example, in some embodiments, each computing environment is maintained as a software environment executed by specially configured hardware as described herein. In one or more particular example embodiments, the apparatus 200 maintains a software environment embodying the illustrated computing environments utilizing the various components of the apparatus 200 as described herein.

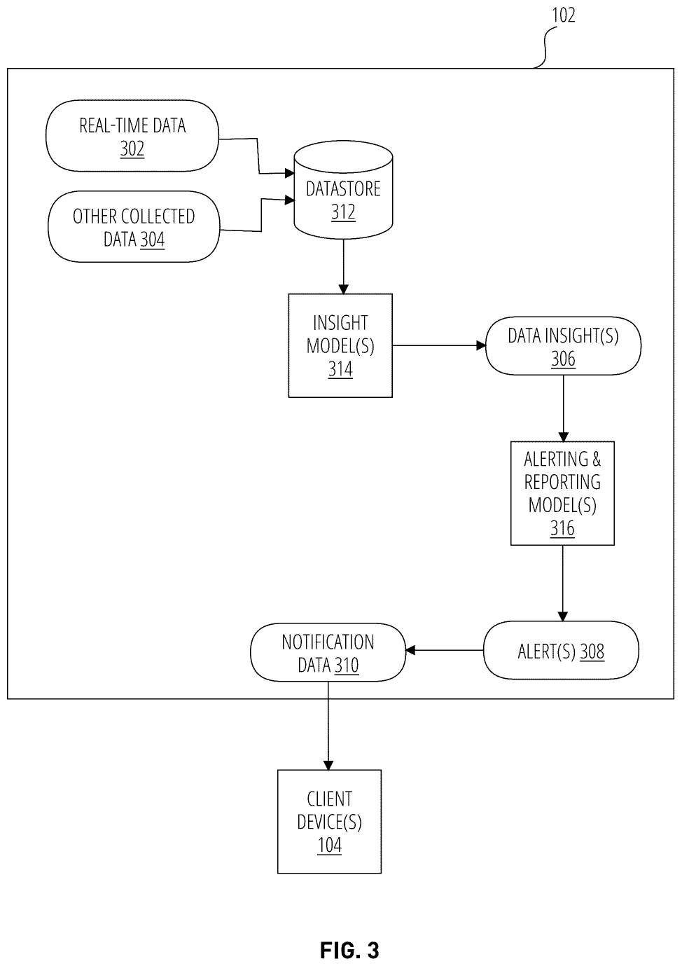

FIG. 3 illustrates an example data flow in an example computing environment in accordance with at least some embodiments of the present disclosure. In some embodiments, the example computing environment is maintained by a data & impact monitoring system 102, for example embodied by the apparatus 200. It should be appreciated that the computing environment may be maintained via one or more software application(s) executing via the apparatus 200.

The computing environment includes a datastore 312. The datastore 312 may include one or more sub-datastores that maintain any number of portions of monitored data, for example real-time monitored data 302 and other collected data 304. In some embodiments, the real-time monitored data 302 includes data collected from sensor(s) within one or more environment(s). Such collected data may indicate current operational aspects of the environment(s), for example affecting temperature, air quality, utility usage, system activation, and/or other physical elements of the environment. The other collected data 304 may include any other data, including non-real-time monitored data collected via sensor(s) in environment(s) and/or via external and/or third-party system(s). In some embodiments, the other collected data 304 includes survey data, aggregated data and/or report(s), financial data, and/or the like that is associated with a historical timestamp or historical interval of time. In some embodiments, the other collected data 304 similarly indicates or includes data values associated with operational aspects of one or more environment(s). In some embodiments, the data & impact monitoring system 102 embodied by apparatus 200 causes storing of monitored data as it is received from external sensor(s), system(s), ad/or the like.

In the depicted computing environment, data from the datastore 312 is retrieved and applied to insight model(s) 314. In some embodiments, the insight model(s) 314 includes algorithmic, statistical, machine learning, and/or AI model(s) that takes monitored data as input and outputs data insight(s) associated therewith. Specifically as illustrated, the insight model(s) 314 receive as input the real-time monitored data 302 and/or other collected data 304 to output corresponding data insight(s) 306. In some embodiments, the data insight(s) include score(s) for one or more metric(s) determined and/or tracked by the apparatus 200. Additionally or alternatively, in some embodiments, the data insight(s) include any other data-driven determination(s) based at least in part on the data values represented by the processed monitored data, for example real-time monitored data 302 and/or other collected data 304. Alternatively or additionally, in some embodiments, at least one data insight of the data insight(s) 306 includes a data value determined from the monitored data without further processing.

In the depicted computing environment, the data insight(s) 306 is/are processable via one or more alerting & reporting model(s) 316. In some embodiments, the alerting & reporting model(s) 316 includes one or more algorithmic, statistical, machine learning, and/or artificial intelligence models that generate and/or otherwise determine one or more alert(s) based at least in part on the inputted data. For example, in some embodiments, the alerting & reporting model(s) 316 includes one or more such model(s) that generate and/or determine one or more alert(s) based on the data insight(s) 306, for example by comparing the data insight(s) 306 with one or more threshold(s), or otherwise processing the data insight(s) 306 to perform a data-driven determination. In one example context for example, the alerting & reporting model(s) 316 generate and/or determine one or more alert(s) 308 based on the data insight(s) 306 indicating whether particular circumstances have been met associated with operational aspects of the environments based on corresponding data insight(s) 306. The alert(s) 308 may be outputted indicating which of the circumstances were determined, detected, and/or otherwise indicated as affected an environment based on the monitored data corresponding to that environment (e.g., via the data insight(s) 306).

In some embodiments, as depicted in the computing environment, the alert(s) 308 may be utilized to generate one or more notification(s) embodied by notification data 310. The notification data 310 may indicate that certain data-driven determinations have been triggered, particular data-driven thresholds have been reached, and/or the like. In this regard, the notification data 310 may be utilized to trigger a system and/or inform a user when certain alert(s) are triggered. In some embodiments, the notification data 310 includes data for outputting to a client device associated with a user account. The notification data 310 may include data embodying or to be rendered to one or more user interface(s), data transmission(s) to be transmitted via third-party messaging platform(s) (e.g., email, text message, and/or the like), and/or the like. In some embodiments, the notification data 310 indicates particular data, alert(s) identified, and/or the like for outputting via a client device.

As depicted, in some embodiments the data & impact monitoring system 102 transmits the notification data 310 to the client device(s) 104 to output particular data. For example, in some embodiments, the data & impact monitoring system 102 transmits the notification data 310 to cause the client device(s) 104 to render a particular user interface based at least in part on the notification data 310. Alternatively or additionally, in some embodiments, the data & impact monitoring system 102 outputs the notification data 310 to the client device(s) 104 via one or more third-party platform(s), for example an email platform, a text messaging platform, or a push notification platform associated with the client device(s) 104.

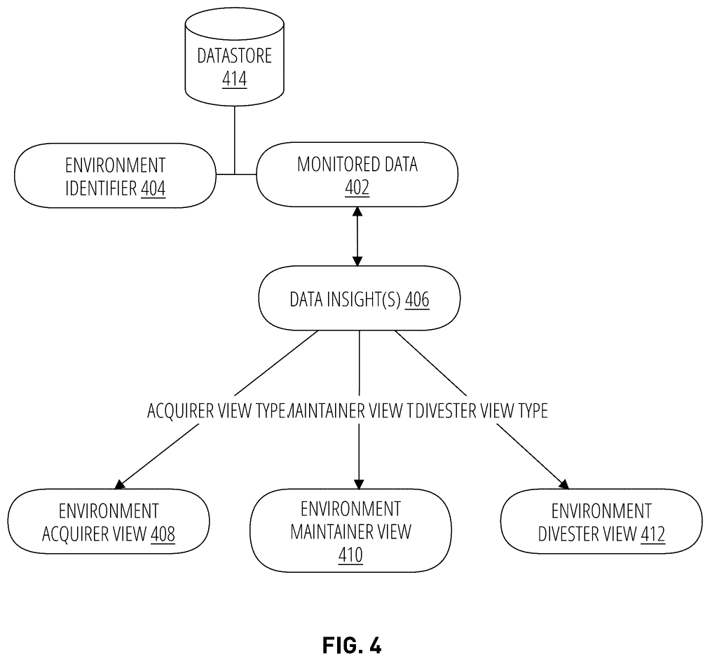

FIG. 4 illustrates an example data flow for deriving data insight(s) for a particular environment and outputting corresponding data to one or more view(s) in accordance with at least some embodiments of the present disclosure. In some embodiments, the data flow is performed by the data & impact monitoring system 102 embodied by the apparatus 200. Specifically, the apparatus 200 may perform the data flow in one or more computing environment(s) to generate the particular view(s) described herein for outputting.

In some embodiments, the apparatus 200 maintains the datastore 414 with a plurality of data portions, for example portions of monitored data 402. In some embodiments, each portion of the monitored data 402 is stored in the datastore 414 together with an environment identifier, for example the environment identifier 404. The environment identifier 404 may uniquely identify a particular environment, for example using a unique alphanumeric string and/or the like. In this regard, to obtain the monitored data particularly associated with a particular environment, the datastore 414 may be queried based at least in part on the particular environment identifier 404 corresponding to the particular environment for processing. In some embodiments, the apparatus 200 automatically identifies an environment identifier 404 for processing. In other embodiments, a user selects the particular environment identifier 404, for example by providing user input via one or more user interface(s).

As described herein, in some embodiments the apparatus 200 processes the monitored data 402 to generate data insight(s) 406. In some embodiments, the apparatus 200 generates the data insight(s) 406 via one or more insight model(s) that take the monitored data 402 associated with one or more environment(s) as input and outputs the data insight(s) 406 based at least in part on the monitored data 402. The data insight(s) may include data-driven determination(s), derived score(s), and/or other data that provides insight into operational aspects of the environment(s). Additionally or alternatively, in some embodiments, the apparatus 200 generates one or more alert(s) based at least in part on the data insight(s) 406 and/or the monitored data 402 directly.

In some embodiments, the apparatus 200 utilizes the various data available, including the monitored data 402, data insight(s) 406, and/or alert(s) associated therewith, to customize one or more view(s) for outputting, for example via one or more client device(s) associated with the apparatus 200. In some embodiments, the customized view includes different data insight(s) of the data insight(s) 406, different alert(s) associated therewith, and/or different portions of the monitored data 402. In some embodiments, the apparatus 200 enables a user to provide user input that selects a particular view type for use in outputting a particular view. Alternatively or additionally, in some embodiments, the apparatus 200 enables a user to register or otherwise configure a user account associated with a particular user type, where the user type is associated with a particular data view.

In some embodiments, the apparatus 200 enables access to at least an acquirer view type, a maintainer view type, and/or a divester view type. Each of the view types may be utilized to customize and/or otherwise configure a particular view for outputting via the apparatus 200 or a corresponding client device. For example, the acquirer view type may be utilized to configure an environment acquirer view 408, the maintainer view type may be utilized to configure an environment maintainer view 410, and the divester view type may be utilized to configure an environment divester view 412.

In some embodiments, the environment acquirer view 408 associated with the acquirer view type includes one or more first user interface elements configured based on particular data insight(s), portions of monitored data, and/or alert(s). For example, such first user interface elements may be configured to provide particular data relevant to an investor or other acquirer of an environment or environment portfolio. In one example context, the first user interface elements includes a graph or label depiction of environment value data, alert impact data, ownership information, and/or the like, at a particular time interval or over a timeseries. Additionally or alternatively, in some embodiments the environment maintainer view 410 associated with the maintainer view type includes one or more second user interface elements that provide particular data relevant to a current owner or maintainer of an environment or environment portfolio. In one example context, the second user interface elements depict a graph or label depiction of operational aspects, maintenance items, derived score(s) for one or more metric(s), alert impact data, and/or the like associated with operation of an environment or an environment portfolio. Alternatively or additionally, in some embodiments, the environment divester view 412 associated with the divester view type includes one or more third user interface elements that provide particular data relevant to a user seeking divestment of an environment or environment portfolio. In one example context, the third user interface elements depict a graph or label description of environment value data, alert impact data, environment improvement recommendation(s) and/or effects of potential environment improvement recommendation(s) on other data associated with the environment or environment portfolio, and/or the like. It will be appreciated that in this regard, the apparatus 200 may customize the particular view for outputting to include details relevant based on the corresponding view type from a candidate set of view types, where any number of candidate view types may be configured.

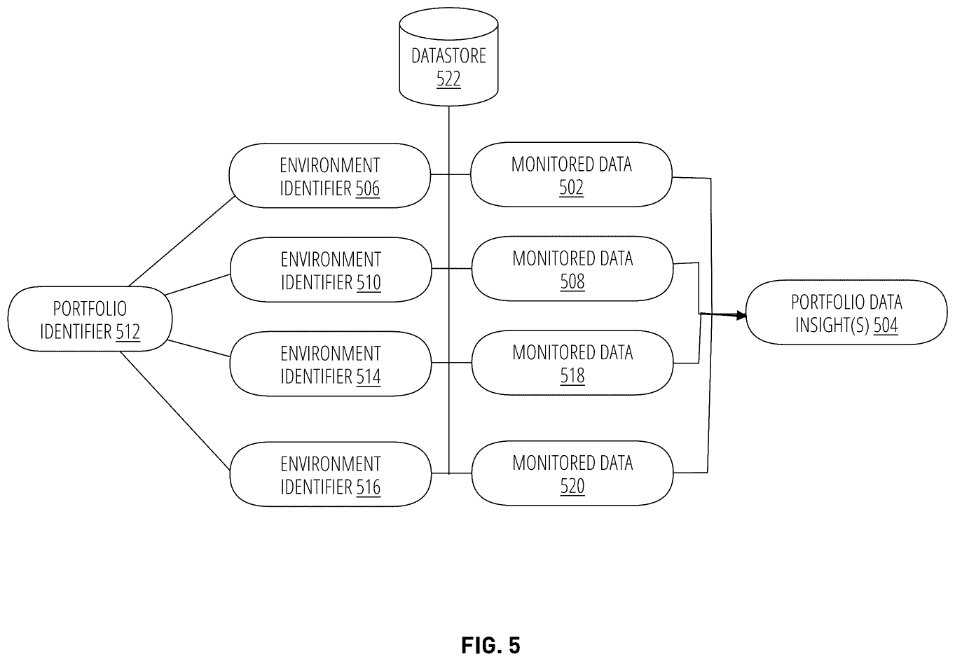

FIG. 5 illustrates an example data flow for deriving portfolio-level data insight(s) for a particular plurality of environments in accordance with at least some embodiments of the present disclosure. In some embodiments, the data is maintained by and/or the data flow is performed by the data & impact monitoring system 102 embodied by the apparatus 200. Specifically, the apparatus 200 may perform the data flow in one or more computing environment(s) to generate the particular portfolio-level data insight(s) as described herein.

As depicted, the apparatus 200 may maintain a datastore 522 including a plurality of portions of monitored data, for example the monitored data 502, 508, 514, and/or 518. In some embodiments, each of the portions of monitored data is associated with an environment identifier that uniquely identifies the environment with which such data is associated. For example as depicted, monitored data 502 is associated with environment identifier 506, the monitored data 508 is associated with environment identifier 510, the monitored data 514 is associated with environment identifier 516, and the monitored data 518 is associated with environment identifier 520. In some embodiments, the apparatus 200 automatically associates a portion of monitored data with a corresponding environment identifier based at least in part on the source from which the monitored data was received (e.g., where particular sensor(s) within an environment are predetermined to be associated with a particular environment identifier corresponding to that identifier), or based at least in part on user input identifying the environment identifier.

In some embodiments, the apparatus 200 further enables linking of a plurality of environments together. In one example context, the linking of a plurality of environments indicates ownership, control, or other association of the plurality of environments with a single entity, use account, and/or the like. In some embodiments, a portfolio identifier embodies a data tag customized by a user account to link particular environments with shared attributes (e.g., building type, location, region, and/or the like). In some such embodiments, a user account is usable to create a portfolio identifier to be linked to one or more environment(s). In some embodiments, portfolio identifier(s) are automatically generated via the apparatus 200.

As depicted, the environment identifier 506, environment identifier 510, monitored data 514, and monitored data 518 are each associated with the portfolio identifier 512. In some such embodiments, the portfolio identifier 512 may be utilized to identify all environment identifiers associated therewith and/or otherwise retrieve monitored data corresponding to any environment identifiers associated with the portfolio identifier 512. In this regard, the datastore 522 may be queried for example based at least in part on a user-submitted portfolio identifier to identify the environment identifier(s) associated therewith and/or retrieve the monitored data associated with such environment identifiers corresponding to that portfolio identifier. It will be appreciated that in some embodiments the apparatus 200 may be utilized to associate and/or disassociate any number of environment identifiers with a particular portfolio identifier.

In some embodiments, the apparatus 200 utilizes the various portions of monitored data corresponding to environment identifiers associated with a particular portfolio identifier to generate and/or derive one or more portfolio-level data insight(s). For example as depicted, the monitored data 502, monitored data 508, monitored data 514, and monitored data 518 may be processed to generate portfolio data insight(s) 504. In some embodiments, the portfolio data insight(s) 504 include aggregated data insight(s) for each environment represented by environment identifiers corresponding to the portfolio identifier 512, and/or otherwise derived data values based on the various portions of monitored data. In some embodiments, the portfolio data insight(s) 504 includes total alert impact data for an entire environment portfolio by aggregating alert impact data of each environment associated with that environment portfolio, aggregated environment value data, and/or the like. Additionally or alternatively, in some embodiments, the portfolio data insight(s) 504 includes one or more data insight(s) derived from the plurality of monitored data portions utilizing an insight model.

It should be appreciated that similar to portfolio data insight(s) 504, portfolio data alert(s) may be generated for an environment portfolio. For example, such portfolio data alert(s) may indicate that particular threshold(s), or other data-driven triggers or determination(s), have been met across a plurality of monitored data portions for a plurality of environments. In this regard, in some embodiments any of the data processing methodologies described herein may be performed with respect to an individual environment or a plurality of environments accordingly. Similarly, output of data insights and/or monitored data and/or alert(s) may include data associated with a particular environment (e.g., individual environment data insights, monitored data, alert(s), and/or the like), or data associated with an environment portfolio corresponding to a plurality of environments. (e.g., portfolio data insights, portfolio aggregated monitored data, portfolio data alert(s), and/or the like).

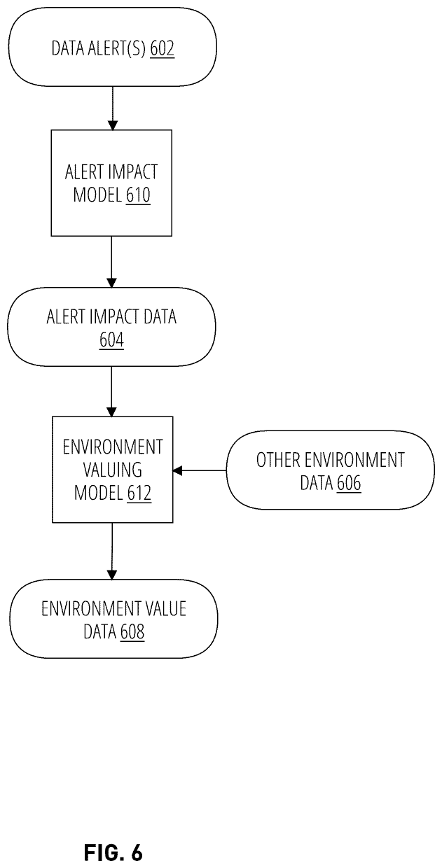

FIG. 6 illustrates an example data flow for environment value data generation in accordance with at least some embodiments of the present disclosure. In some embodiments, the data is maintained by and/or the data flow is performed by the data & impact monitoring system 102 embodied by the apparatus 200. Specifically, the apparatus 200 may perform the data flow in one or more computing environment(s) to generate environment data value(s) for one or more environment(s) as described herein.

In some embodiments, the apparatus 200 utilizes various alert(s) associated with an environment to accurately generate and/or otherwise determine alert impact data associated with the environment. In some embodiments, the alert impact data represents an offset or impact to a value of an environment, for example based on operational inefficiencies associated with the environment. In one example context, alert impact data represents a value of deferred maintenance associated with an environment, such that the deferred maintenance value offsets a valuation of the environment that would be assigned if otherwise all operational aspects of the environment were in full working order (e.g., there were no deferred maintenance).

In some embodiments, the apparatus 200 receives, stores, and/or otherwise identifies data alert(s) 602 for a particular environment. In some embodiments, such data alert(s) 602 may be determined based at least in part on monitored data and/or data insight(s) associated with the environment, as described herein. For example, in some embodiments, the data alert(s) 602 indicate data-driven determination(s), trigger(s) met, threshold(s) satisfied, and/or the like determined from monitored data received associated with the particular environment. Such data alert(s) 602 may indicate for example that a particular data value or combination of data values has fallen below or exceeded a particular threshold, that one or more system(s) associated with an environment is indicated as malfunctioning based on its operational data or transmission(s) received from or associated with the system, that one or more system(s) have gone offline, and/or the like. In some embodiments, each data alert indicates that an environment is experiencing a problematic circumstance impacting one or more operational aspects of the environment.

In some embodiments, the apparatus 200 applies the data alert(s) 602 to an alert impact model 610. The alert impact model 610 may embody an algorithmic, statistical, machine learning, and/or artificial intelligence model specially trained to generate alert impact data, such as the alert impact data 604 based at least in part on the inputted data alert(s) 602. In some embodiments, the alert impact model 610 embodies a machine-learning model specially trained based at least in part on historical alert(s) for the environment and/or other environment(s) and corresponding alert impact data contributed to by said each historical alert(s). In this regard, the alert impact model 610 may be specially trained to identify to what and/or how much particular alert(s) contribute to alert impact data for a particular environment. In one example context, the alert impact model 610 utilizes alert(s) indicating a problematic circumstance in an environment to determine how much such alert(s) contribute to a deferred maintenance value impact associated with the environment. It should be appreciated that such a determination may be performed independently for any number of environments.

In some embodiments, the apparatus 200 further determines one or more environment value data corresponding to an environment. In some embodiments, the environment value data represents a valuation attributed to an environment. It should be appreciated that the environment value data corresponding to a particular environment may be determined based on any of a myriad of contributing factors. In some embodiments, first environment value data is generated that represents the valuation of an environment in a first form (e.g., pristine condition, without any impact from deferred maintenance). In some such embodiments, the first environment value data may be impacted based at least in part on alert impact data that offsets the value by a particular value (e.g., a value attributable to deferred maintenance costs represents by the alert impact data). In this regard, the first environment value data may be adjusted based at least in part on the alert impact data to generate second environment value data accurately representing the true valuation of the environment, for example, based on its current operational aspects.

As depicted, in some embodiments the environment valuing model 612 generates the environment value data 608 based at least in part on the alert impact data 604 and other environment data 606. In some embodiments, the other environment data 606 includes one or more portion(s) of monitored data, static data associated with an environment (e.g., property characteristics, financial rates for services, and/or the like), and/or any other data that contributes to a data-driven process for determining environment value data for an environment. In some embodiments, the environment valuing model 612 utilizes the other environment data 606 to output and/or otherwise determine first environment value data (e.g., representing a valuation of an environment before offset via the alert impact data 604). Upon determining the first environment value data, the environment valuing model 612 then may adjust the first environment value data utilizing the alert impact data 604, such as by subtracting the alert impact data 604 from the first environment value data, to generate the final environment value data 608.

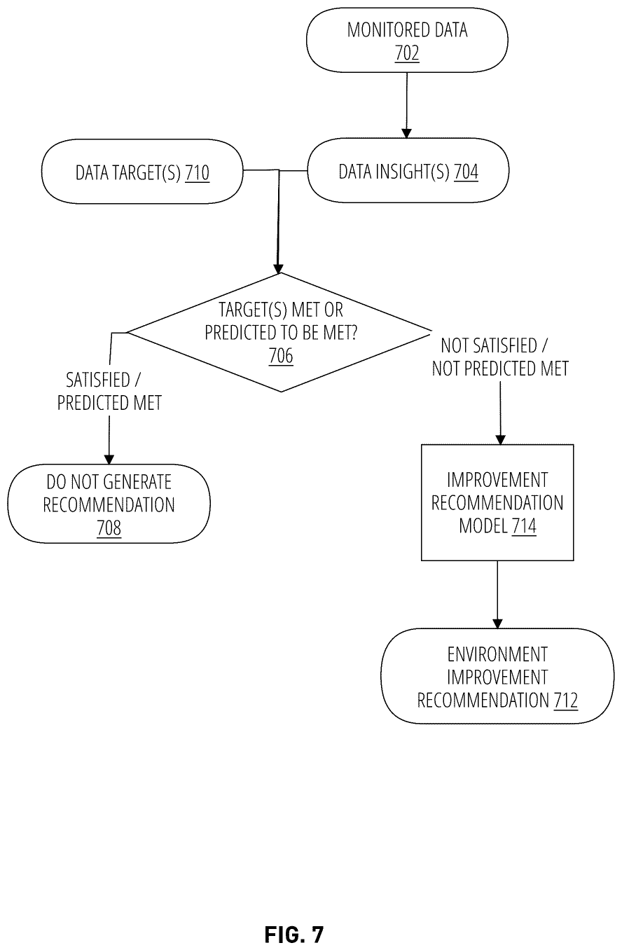

FIG. 7 illustrates an example data flow for environment improvement recommendation determination in accordance with at least some embodiments of the present disclosure. In some embodiments, the data is maintained by and/or the data flow is performed by the data & impact monitoring system 102 embodied by the apparatus 200. Specifically, the apparatus 200 may perform the data flow in one or more computing environment(s) to generate environment improvement recommendation(s) associated with one or more environment(s) as described herein.

In some embodiments, as described herein, the apparatus 200 generates one or more data insight(s) 704 from monitored data 702. In this regard, the data insight(s) 704 may indicate one or more operational aspects for an environment based at least in part on the data values represented in the monitored data 702. It should be appreciated that the data insight(s) 704 may represent operational aspects at any level of granularity. For example, in one example context, a first data insight may represent a data value for operation of a particular heating, ventilation, and air conditioning unit within an environment. Alternatively or additionally, in another example context, a second data insight may represent a data-driven score for a particular comfort metric that is derived from data values associated with temperature, air quality, and/or other comfort-related measurable values from within the environment.

In some embodiments, as depicted in the data flow, the apparatus 200 compares one or more of the data insight(s) 704 with one or more data target(s) 710. In some embodiments, the data target(s) 710 represent threshold data values and/or changes in data values that one or more of the data insight(s) 704 is/are to satisfy over one or more timestamp intervals. For example, in one example context, a data target of the data target(s) 710 embodies a target data value that a carbon emissions data value represented in the data insight(s) 704 is to reach within a predetermined interval of time (e.g., one year). Alternatively or additionally, in another example context, a data target of the data target(s) 710 embodies a target rate of change for a carbon emissions value represented in the data insight(s) 704 is to decrease each month. In some embodiments, the data target(s) 710 are set by and/or derived based at least in part on user-defined rule sets, regulatory rule sets, and/or automatic determinations from the apparatus 200.

The apparatus 200 may determine whether the data target(s) are met or predicted to be met via the comparison at 706. For example, the apparatus 200 may in some embodiments directly compare the value of a data insight of the data insight(s) 704 with a corresponding data target of the data target(s) 710. Alternatively or additionally, in some embodiments the apparatus 200 processes the data insight of the data insight(s) 704, for example to adjust the time interval associated with the data insight and account for time remaining until a particular data target is to be reached. Alternatively or additionally, in some embodiments the apparatus 200 utilizes one or more specially trained models to determine whether a data target of the data target(s) 710 is determined satisfied based at least in part on the data insight(s) 704, for example where the data model is specially trained to output data indicating a probability or determination that a particular data target has been or will be satisfied.

In some embodiments, in a circumstance where the apparatus 200 determines that a data target was determined or predicted to be satisfied, the apparatus 200 may not generate any environment improvement recommendation as depicted at 708. The apparatus 200 may continue to monitor such data until it is determined that the data target was determined or predicted not to be satisfied. In a circumstance where the apparatus 200 determines or predicts that the data target will not be satisfied, the apparatus 200 may continue processing data in accordance with the data flow for generating an environment improvement recommendation.

In some embodiments, the apparatus 200 applies one or more portion(s) of data to an improvement recommendation model 714. In some embodiments, the improvement recommendation model 714 embodies a specially trained algorithmic, statistical, machine learning, and/or artificial intelligence model that outputs one or more environment improvement recommendation(s) based at least in part on input data received by the model. In some embodiments, the improvement recommendation model 714 receives as input the data insight(s) 704, data insight(s) 704, monitored data 702, and/or alert(s) or other data associated with the environment. In some embodiments, the improvement recommendation model 714 determines particular environment improvement recommendation(s) that are determined or otherwise predicted to improve the data insight(s) 704 to satisfy corresponding data target(s) 710. In some embodiments, the environment improvement recommendation 712 is trained based at least in part on data indicating historical actions performed, such as environment improvement recommendation(s), and corresponding changes to data insight(s) based at least in part on such action(s). The environment improvement recommendation 712 may be determined to most improve one or more data insight(s) of the data insight(s) 704 with respect to the data target(s) 710, and in some contexts the improvement recommendation model 714 determines particular environment improvement recommendation(s) based at least in part on constrained resource value(s) inputted to the improvement recommendation model 714. For example, in some embodiments each environment improvement recommendation may be associated with a particular resource value, such that the environment improvement recommendation(s) outputted via the improvement recommendation model 714 must not exceed the constrained resource value. Non-limiting examples of a constrained resource value include a maximum cost associated with environment improvement recommendations (e.g., such that the outputted environment improvement recommendation cannot cost above available currency resources), a maximum time allocation associated with environment improvement recommendations (e.g., such that the time to perform the outputted environment improvement recommendation cannot take above an available length of time), a maximum manpower allocation associated with the environment improvement recommendations (e.g., such that the number of persons required to perform the environment improvement recommendation cannot exceed a maximum available number of personnel), and/or the like. In this regard, in some such embodiments, the improvement recommendation model 714 may be specially trained to select and output the environment improvement recommendation(s) that best improve the data insight(s) 704 while satisfying the constraints set forth by the constrained resource value. In some embodiments, the improvement recommendation model 714 determines and/or outputs the environment improvement recommendation 712 such that the environment improvement recommendation 712 may be outputted via the apparatus 200, for example as notification data, via one or more user interface(s), and/or the like.

### Example Processes of the Disclosure

Having described example systems, apparatuses, and data flows associated with embodiments of the present disclosure, example computer-implemented processes of the disclosure will now be discussed. It should be appreciated that each of the flowcharts herein depicts an example computer-implemented process that may be performed by one or more of the apparatuses, systems, and/or devices described herein, for example utilizing any one or more of the components thereof. The blocks indicating operations of each process may be arranged in any of a number of ways, as depicted and described herein. In some such embodiments, one or more blocks of any of the processes described herein occur in-between one or more blocks of another process, before one or more blocks of another process, and/or otherwise operates as a sun-process of a second process. Additionally or alternative, any of the processes may include some or all of the steps described and/or depicted, including one or more optional operational blocks in some embodiments. In regards to the below flowcharts, one or more of the depicted blocks may be optional in some, or all, embodiments of the disclosure. Optional blocks are depicted with broken (or “dashed”) lines. Similarly, it should be appreciated that one or more of the operations of each flowchart may be combinable, replaceable, and/or otherwise altered as described herein.

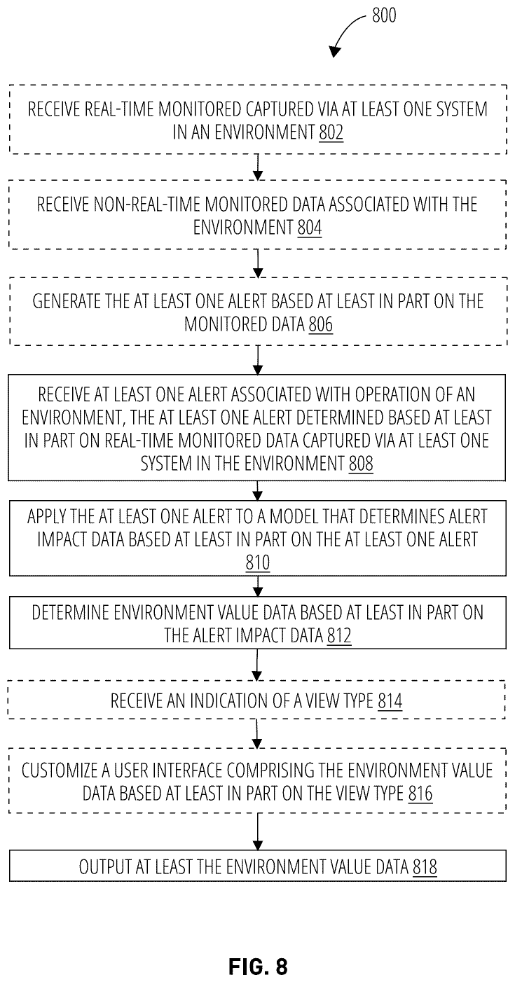

FIG. 8 illustrates a flowchart including operations of an example process for accurately determining and using alert impact data in accordance with at least one example embodiment of the present disclosure. In some embodiments, the computer-implemented process 800 is embodied by computer program code stored on a non-transitory computer-readable medium of a computer program product configured for execution to perform the computer-implemented method. Alternatively or additionally, in some embodiments, the example process 800 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 800. In some embodiments, the specially configured apparatus 200 includes and/or otherwise is in communication with one or more external apparatuses, systems, devices, and/or the like, to perform one or more of the operations as depicted and described.

The process 800 begins at optional operation 802. At optional operation 802, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that receives real-time monitored data captured via at least one system in an environment. In this regard, the real-time monitored data represents current operational aspects of the environment, as determined from real-time data captured from the environment itself. In some embodiments, the apparatus 200 receives the real-time monitored data directly from the sensor(s) in the environment. In other embodiments, the apparatus 200 receives the real-time monitored data indirectly via one or more intermediary systems, for example that aggregate, store, forward, and/or otherwise transmit the sensor data to the apparatus 200. The sensor(s) may include smart systems in the environment, utility systems, Internet-of-Things enabled devices, hazardous condition sensor(s) (e.g., smoke, gas, and/or fire detectors), air quality sensors, temperature sensors or other physical property sensors, and/or the like.

At optional operation 804, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that receives non-real-time monitored data associated with the environment. In some embodiments, the apparatus 200 receives the non-real-time monitored data by retrieving such data from one or more datastores accessible to the apparatus 200. Alternatively or additionally, in some embodiments the apparatus 200 receives the non-real-time monitored data from one or more external data system(s). In some embodiments, the non-real-time monitored data includes survey data from users or occupants of an environment, scraped or other parsed data associated with an environment, and/or the like.

In some embodiments, the apparatus 200 receives monitored data. The monitored data may include the real-time monitored data, non-real-time monitored data, and/or a combination of both. It will be appreciated that in some embodiments, only one of the non-real-time monitored data and/or real-time monitored data is received as monitored data. Additionally or alternatively, in some embodiments, different portions of the monitored data are received at different timestamps and/or intervals. For example, real-time monitored data may be updated continuously or near-continuously, whereas non-real-time monitored data may be updated at predefined intervals of hours, days, weeks, monthly, and/or the like.

At optional operation 806, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that generates at least one alert based at least in part on the monitored data. In some embodiments, the monitored data and/or data insight(s) derived therefrom are utilized to generate the at least one alert. The alert may indicate that any of a number of data-driven determinations, data-driven triggers were triggered, data thresholds were not satisfied, and/or the like. For example, in some embodiments the apparatus 200 compares one or more data values of the monitored data, and/or data insight(s) derived therefrom, with one or more data target(s) and/or thresholds to determine whether an alert should be generated. The apparatus 200 may generate an alert in response to any data-driven determination reaching a particular result.

At operation 808, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that receives at least one alert associated with operation of an environment. In some embodiments, the at least one alert is determined based at least in part on the real-time monitored data captured via at least one system in the environment. In some embodiments, the apparatus 200 receives the alert(s) generated at operation 806. In other embodiments, the apparatus 200 receives the alert(s) generated by another system communicable with the apparatus 200. Alternatively or additionally, in some embodiments the apparatus 200 receives historical alert(s) that were previously generated associated with the environment, for example within a particular timestamp interval (e.g., last 24 hours, last week, and/or the like).

At operation 810, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that applies the at least one alert to a model that determines alert impact data based at least in part on the at least one alert. In some embodiments, the model embodies a specially configured alert impact model, for example embodied as a specially trained machine learning model that outputs alert impact data based at least in part on inputted alert(s). In some embodiments, the alert impact data embodies a data value utilized to offset and/or otherwise adjust environment value data corresponding to the environment for which data was received.

At operation 812, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that determines an environment value data based at least in part on the alert impact data. In some embodiments, the apparatus 200 generates and/or otherwise receives first environment value data associated with the environment, and adjusts the first environment value data utilizing alert impact data. The resulting adjusted environment value data may then embody the final environment value data for further use.

At optional operation 814, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that receives an indication of a view type. In some embodiments, the view type is determined in response to user input, for example representing a selection of a view type by a user. In some embodiments, the view type is automatically identified based at least in part on a user account.

At optional operation 816, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that customizes a user interface comprising the environment value data. In some embodiments, the user interface is customized to include particular user interface elements corresponding to particular data values, data insight(s), and/or the like, based at least in part on the view type. For example, in some embodiments the apparatus 200 customizes a user interface to include a first user interface element for displaying a first data insight in a circumstance where the view type is a first view type, and may customize the user interface to include a second, different user interface element for displaying a second data insight in a circumstance where the view type is a second view type. In some embodiments, the apparatus 200 may store predetermined data indicating the particular user interface element(s) and/or corresponding data insight(s) for each view type.

At operation 818, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that outputs at least the environment value data. In some embodiments, the apparatus 200 outputs the user interface customized at operation 816. In other embodiments, the apparatus 200 outputs a dashboard or other user interface, or sub-interface, including at least the environment value data. Alternatively or additionally, in some embodiments, the apparatus 200 outputs at least the alert impact data, and may but need not output the corresponding environment value data.

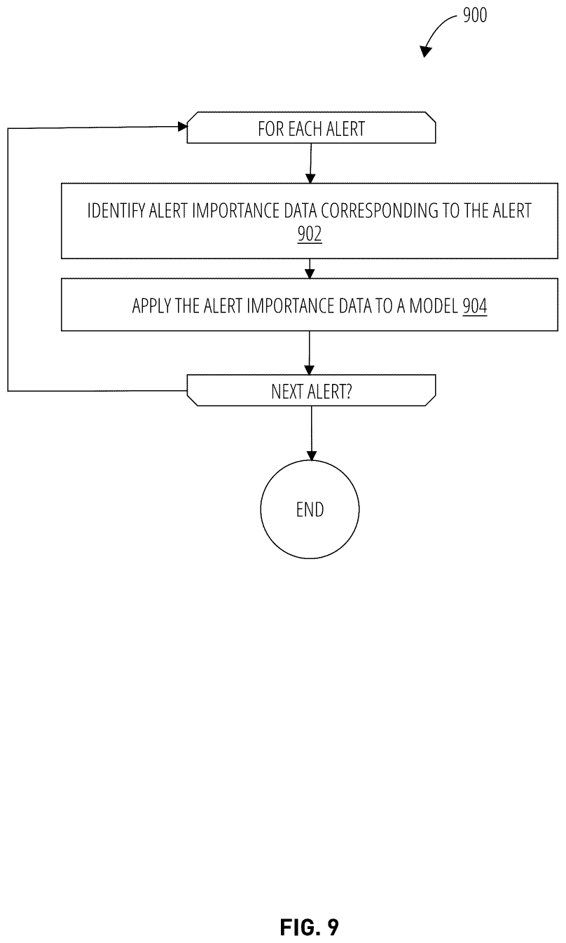

FIG. 9 illustrates an example process 900 for determining alert impact data for at least one alert in accordance with at least some embodiments of the present disclosure. Specifically, FIG. 9 depicts an example process 900 for determining alert impact data based at least in part on alert importance data. In some embodiments, the computer-implemented process 900 is embodied by computer program code stored on a non-transitory computer-readable medium of a computer program product configured for execution to perform the computer-implemented method. Alternatively or additionally, in some embodiments, the example process 900 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 900. In some embodiments, the specially configured apparatus 200 includes and/or otherwise is in communication with one or more external apparatuses, systems, devices, and/or the like, to perform one or more of the operations as depicted and described.

The process 900 begins at operation 902. In some embodiments, the process 900 begins after one or more operations of another process, such as the operation 808 of the process 800 as depicted and described. Additionally or alternatively, in some embodiments, upon completion of the process 900 flow proceeds to one or more operations of another process, such as the operation 812 as depicted and described. In this regard, some or all of the process 900 may replace or supplement one or more blocks depicted and/or described with respect to any of the processes described herein. Upon completion of the process 900, the flow of operations may terminate. Additionally or alternatively, as depicted, upon completion of the process 900 in some embodiments, flow may return to one or more operation(s) of another process, such as the operation 808. It will be appreciated that, in some embodiments, the process 900 embodies a sub-process of one or more other process(es) depicted and/or described herein, for example the process 800.

In some embodiments, the process 900 is repeated for any number of times for processing any number of alerts. For example, in some embodiments, the process 900 is repeated for each alert of the at least one alert received at operation 806, as described herein. In this regard, it will be appreciated that “the alert” referred to for a particular iteration of the process 900 may be whichever alert is selected for processing during the current iteration.

At operation 902, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that identifies alert importance data corresponding to the alert. In some embodiments, each alert includes or is received together alert importance data corresponding to that alert. The alert importance data may include one or more data value(s) that indicate or may be used to derive a severity or other importance of an alert on one or more operational aspect(s) of the environment, for example as measured by one or more data insight(s). In some embodiments, the alert includes or otherwise is associated with alert importance data embodying an alert importance value, for example from a set of candidate importance values or along a range of candidate importance values. Alternatively or additionally, in some embodiments, the alert includes or otherwise is associated with alert importance data comprising an alert type, a system type corresponding to the alert, an alert criticality level corresponding to the alert, location data associated with the alert, and/or the like. It will be appreciated that the apparatus 200 may receive and/or otherwise identify any particular data relevant to determination of how important an alert may be.

At operation 904, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that applies the alert importance data to a model. In some embodiments, the apparatus 200 applies the alert importance data as an input to an alert impact model, where the alert impact model generates alert impact data based at least in part on the alert importance data. For example, in some embodiments, the model is trained at least in part on features that consider the alert importance data and/or one or more portions thereof to determine the alert impact data.

In some embodiments, the apparatus 200 generates alert impact data based at least in part on individual data portion(s) contributed by each of the at least one alerts. For example, in some embodiments, the apparatus 200 generates or otherwise determines a portion of alert impact data for each alert, and aggregates the portions of alert impact data to determine the alert impact data for all of the at least one alerts.

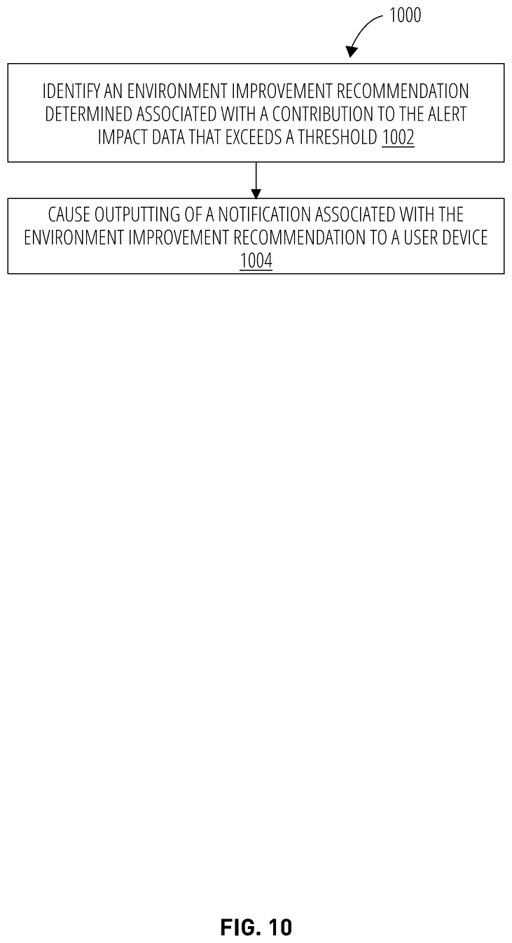

FIG. 10 illustrates an example process 1000 for identifying and outputting an environment improvement recommendation sufficiently contributing to alert impact data in accordance with at least some embodiments of the present disclosure. Specifically, FIG. 10 depicts an example process 1000 for outputting an environment improvement recommendation that improves the alert impact data for a particular environment. In some embodiments, the computer-implemented process 1000 is embodied by computer program code stored on a non-transitory computer-readable medium of a computer program product configured for execution to perform the computer-implemented method. Alternatively or additionally, in some embodiments, the example process 1000 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 1000. In some embodiments, the specially configured apparatus 200 includes and/or otherwise is in communication with one or more external apparatuses, systems, devices, and/or the like, to perform one or more of the operations as depicted and described.

The process 1000 begins at operation 1002. In some embodiments, the process 1000 begins after one or more operations of another process, such as the operation 818 of the process 800 as depicted and described. Additionally or alternatively, in some embodiments, upon completion of the process 1000 flow proceeds to one or more operations of another process. In this regard, some or all of the process 1000 may replace or supplement one or more blocks depicted and/or described with respect to any of the processes described herein. Upon completion of the process 1000, the flow of operations may terminate. It will be appreciated that, in some embodiments, the process 1000 embodies a sub-process of one or more other process(es) depicted and/or described herein, for example the process 800.

At operation 1002, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that identifies an environment improvement recommendation. In some embodiments, the environment improvement recommendation is determined associated with a contribution to the alert impact data that exceeds a threshold. For example, in some embodiments, the apparatus 200 models or otherwise determines an effect that a particular environment improvement recommendation may have on one or more data insight(s) and/or corresponding alert impact data for a particular environment. Additionally or alternatively, in some embodiments, an environment improvement recommendation is associated with a predefined improvement to alert impact data. In one such embodiment, the apparatus 200 identifies a predetermined contribution to the alert impact data associated with an environment improvement recommendation, for example such that implementation of the environment improvement recommendation is determined to likely improve the alert impact data by reducing or eliminating particular alert(s). In some embodiments, the apparatus 200 determines a contribution for each alert to the alert impact data, and determines an environment improvement recommendation that is determined (e.g., via one or more model(s), preconfigured data links, and/or other algorithm(s)) to resolve or most reduce the contribution of such alert(s).

At operation 1004, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that causes outputting of a notification associated with the environment improvement recommendation. In some embodiments, the notification is outputted to a user device. In some embodiments, the apparatus 200 outputs the notification as part of a user interface including environment value data, alert impact data, and/or the like. Alternatively or additionally, in some embodiments the apparatus 200 outputs the notification as a separate transmission, for example to be rendered via a push notification, text message, email, and/or the like. In some embodiments, the user device embodies a client device connected with the apparatus 200 via an authenticated session. In other embodiments, the user device embodies a determinable computing device associated with the environment.

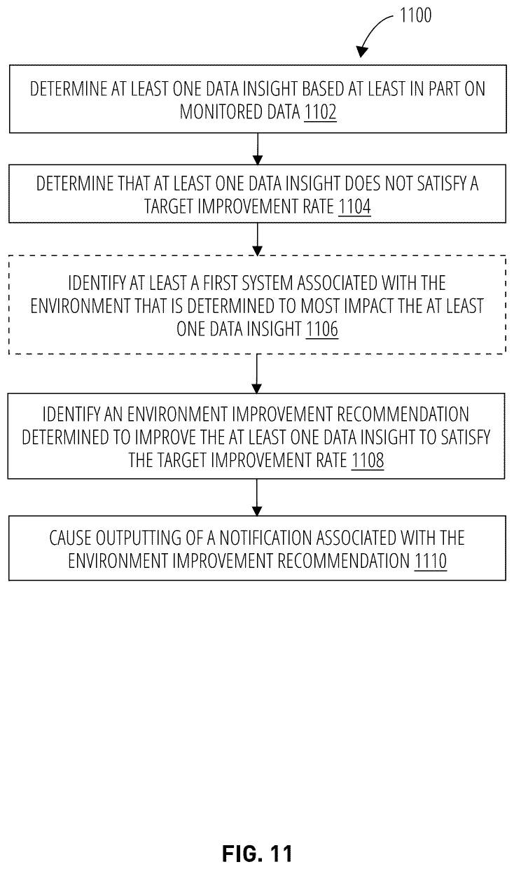

FIG. 11 illustrates an example process 1100 for identifying and outputting an environment improvement recommendation to satisfy a target improvement rate in accordance with at least some embodiments of the present disclosure. Specifically, FIG. 11 depicts an example process 1100 for outputting an environment improvement recommendation that improves a data insight for a particular environment to hit a target improvement rate. In some embodiments, the computer-implemented process 1100 is embodied by computer program code stored on a non-transitory computer-readable medium of a computer program product configured for execution to perform the computer-implemented method. Alternatively or additionally, in some embodiments, the example process 1100 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 1100. In some embodiments, the specially configured apparatus 200 includes and/or otherwise is in communication with one or more external apparatuses, systems, devices, and/or the like, to perform one or more of the operations as depicted and described.

The process 1100 begins at operation 1102. In some embodiments, the process 1100 begins after one or more operations of another process, such as the operation 818 of the process 800 as depicted and described. Additionally or alternatively, in some embodiments, upon completion of the process 1100 flow proceeds to one or more operations of another process. In this regard, some or all of the process 1100 may replace or supplement one or more blocks depicted and/or described with respect to any of the processes described herein. Upon completion of the process 1100, the flow of operations may terminate. It will be appreciated that, in some embodiments, the process 1100 embodies a sub-process of one or more other process(es) depicted and/or described herein, for example the process 800.

At operation 1102, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that determines at least one data insight based at least in part on monitored data. In some embodiments, the at least one data insight is determined based at least in part on real-time monitored data (for example received at operation 802), and/or non-real-time monitored data (for example received at operation 804) associated with the particular environment. In some embodiments, the at least one data insight represents one or more operational aspects of the environment. In some embodiments, the at least one data insight includes a score for at least one metric representing an operational aspect of the environment. Alternatively or additionally, in some embodiments, the at least one data insight includes a raw data value from the monitored data.

At operation 1104, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that determines that at least one of the at least one data insights does not satisfy a target improvement rate. In some embodiments, a target improvement rate represents a target change in a data value associated with the at least one data insight over a particular timestamp interval. In some embodiments, the apparatus 200 determines the data insight(s) that do not satisfy a target improvement rate based on one or more historical record(s) corresponding to the data insight, for example such that the apparatus 200 may determine a change in the data insight over time. In some embodiments, the target improvement rate for a particular data insight is determined based at least in part on user input (e.g., selecting or otherwise inputting a target improvement rate), a rule set maintained by the apparatus 200, a regulatory rule set associated with a particular data insight, and/or the like.

At optional operation 1106, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that identifies at least a first system associated with the environment that is determined to most impact the at least one data insight. In some embodiments, the apparatus 200 identifies the system as corresponding to portions of the monitored data utilized to determine the data insight. Additionally or alternatively, in some embodiments the apparatus 200 determines systems that are associated with one or more alert(s), and/or highest importance alerts (e.g., based on corresponding alert importance data for such alerts).

At operation 1108, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that identifies an environment improvement recommendation determined to improve the at least one data insight to satisfy the target improvement rate. In some embodiments, each candidate environment improvement recommendation is associated with a predetermined improvement to one or more portions of monitored data that contribute to the particular data insight. In some embodiments, the environment improvement recommendation is associated with improvement to the system identified at operation 1106. Alternatively or additionally, in some embodiments, the apparatus 200 utilizes one or more model(s) maintained by the apparatus 200 to determine how much improvement to the data insight would be provided by a particular environment improvement recommendation.

At operation 1110, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that causes outputting of a notification associated with the environment improvement recommendation. For example, the notification may identify the environment improvement recommendation and/or indicate the determined or predicted improvement to the data insight that the environment improvement recommendation provides. In some embodiments, the notification is outputted to a user device. In some embodiments, the apparatus 200 outputs the notification as part of a user interface including environment value data, alert impact data, and/or the like. Alternatively or additionally, in some embodiments the apparatus 200 outputs the notification as a separate transmission, for example to be rendered via a push notification, text message, email, and/or the like. In some embodiments, the user device embodies a client device connected with the apparatus 200 via an authenticated session. In other embodiments, the user device embodies a determinable computing device associated with the environment.

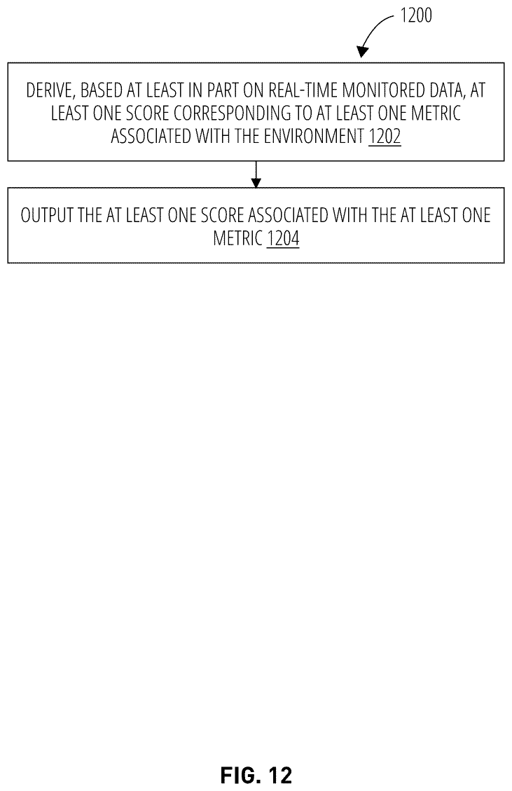

FIG. 12 illustrates an example process 1200 for deriving and outputting scores for at least one metric in accordance with at least some embodiments of the present disclosure. Specifically, FIG. 12 depicts an example process 1200 for determining a data insight embodied by a score for a particular metric representing an operational aspect of an environment. In some embodiments, the computer-implemented process 1200 is embodied by computer program code stored on a non-transitory computer-readable medium of a computer program product configured for execution to perform the computer-implemented method. Alternatively or additionally, in some embodiments, the example process 1200 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 1200. In some embodiments, the specially configured apparatus 200 includes and/or otherwise is in communication with one or more external apparatuses, systems, devices, and/or the like, to perform one or more of the operations as depicted and described.

The process 1200 begins at operation 1202. In some embodiments, the process 1200 begins after one or more operations of another process, such as the operation 818 of the process 800 as depicted and described. Additionally or alternatively, in some embodiments, upon completion of the process 1200 flow proceeds to one or more operations of another process. In this regard, some or all of the process 1200 may replace or supplement one or more blocks depicted and/or described with respect to any of the processes described herein. Upon completion of the process 1200, the flow of operations may terminate. It will be appreciated that, in some embodiments, the process 1200 embodies a sub-process of one or more other process(es) depicted and/or described herein, for example the process 800.

At operation 1202, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that derives, based at least in part on real-time monitored data, at least one score corresponding to at least one metric associated with the environment. In some embodiments, the score corresponding to the at least one metric is determined utilizing a particular determined or predefined algorithm. In some such embodiments, the algorithm may utilize monitored data, including at least the real-time monitored data, as input and transform the inputted monitored data to the score. It should be appreciated that in some embodiments, scores for different metrics are derived based at least in part on different portions of monitored data.

At operation 1204, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that outputs the at least one score associated with the at least one metric. In some embodiments, the at least one score is outputted to a user device. In some embodiments, the apparatus 200 outputs the at least one score associated with the at least one metric as part of a user interface including environment value data, alert impact data, and/or the like. For example, the at least one score may be outputted as a graph (e.g., together with historical scores for the at least one metric), a data label, and/or the like. Alternatively or additionally, in some embodiments the apparatus 200 outputs the at least one score as a separate transmission, for example to be rendered via a push notification, text message, email, and/or the like. In some embodiments, the user device embodies a client device connected with the apparatus 200 via an authenticated session. In other embodiments, the user device embodies a determinable computing device associated with the environment.

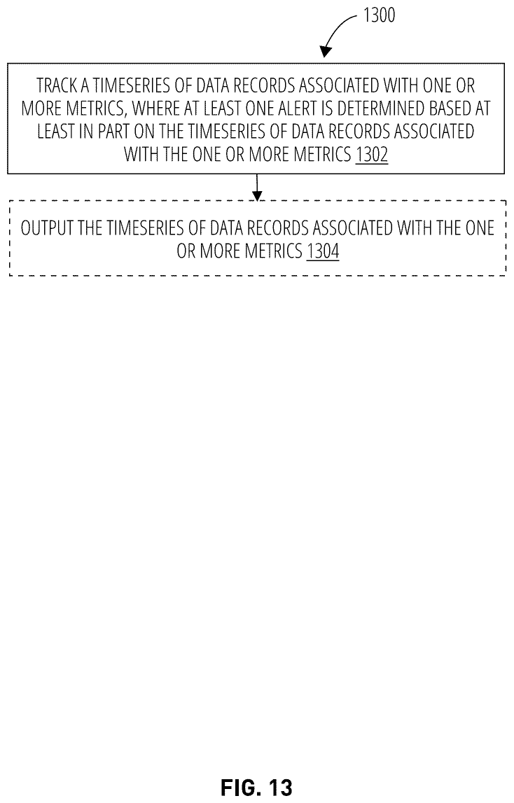

FIG. 13 illustrates an example process 1300 for tracking and outputting a timeseries of data records in accordance with at least some embodiments of the present disclosure. Specifically, FIG. 13 depicts an example process 1300 for maintaining a timeseries of data records, for example embodying or associated with one or more data insight(s). In some embodiments, the computer-implemented process 1300 is embodied by computer program code stored on a non-transitory computer-readable medium of a computer program product configured for execution to perform the computer-implemented method. Alternatively or additionally, in some embodiments, the example process 1300 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 1300. In some embodiments, the specially configured apparatus 200 includes and/or otherwise is in communication with one or more external apparatuses, systems, devices, and/or the like, to perform one or more of the operations as depicted and described.

The process 1300 begins at operation 1302. In some embodiments, the process 1300 begins after one or more operations of another process, such as the operation 804 of the process 800 as depicted and described. Additionally or alternatively, in some embodiments, upon completion of the process 1300 flow proceeds to one or more operations of another process, such as the operation 806 of the process 800 as depicted and described. In this regard, some or all of the process 1300 may replace or supplement one or more blocks depicted and/or described with respect to any of the processes described herein. Upon completion of the process 1300, the flow of operations may terminate. It will be appreciated that, in some embodiments, the process 1300 embodies a sub-process of one or more other process(es) depicted and/or described herein, for example the process 800.

At operation 1302, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that tracks a timeseries of data records associated with one or more metrics. For example, in some embodiments, each data record embodies a historical data value (e.g., a score) corresponding to a metric of the one or more metrics. In some embodiments, the apparatus 200 stores each score for a particular metric as it is generated or otherwise derived, for example as a data record in one or more datastore(s) maintained by or otherwise accessible to the apparatus 200. In some such embodiments, at least one alert is determined based at least in part on the timeseries of data records associated with the one or more metrics. For example, in some embodiments a data insight representing a rate of change or improvement of a particular data value or score is determined, and a corresponding alert may be generated in circumstances where the rate of improvement does not satisfy a target improvement rate.

At optional operation 1304, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that outputs the timeseries of data records associated with the one or more metrics. In some embodiments, the apparatus 200 outputs the timeseries of data records as part of a user interface including environment value data, alert impact data, and/or the like. For example, the timeseries of data records may be outputted as a graph (e.g., depicting the change in the data records over time), one or more data label(s), and/or the like. Alternatively or additionally, in some embodiments, the apparatus 200 outputs data value(s), data insight(s), and/or alert(s) derived from the timeseries of data records.

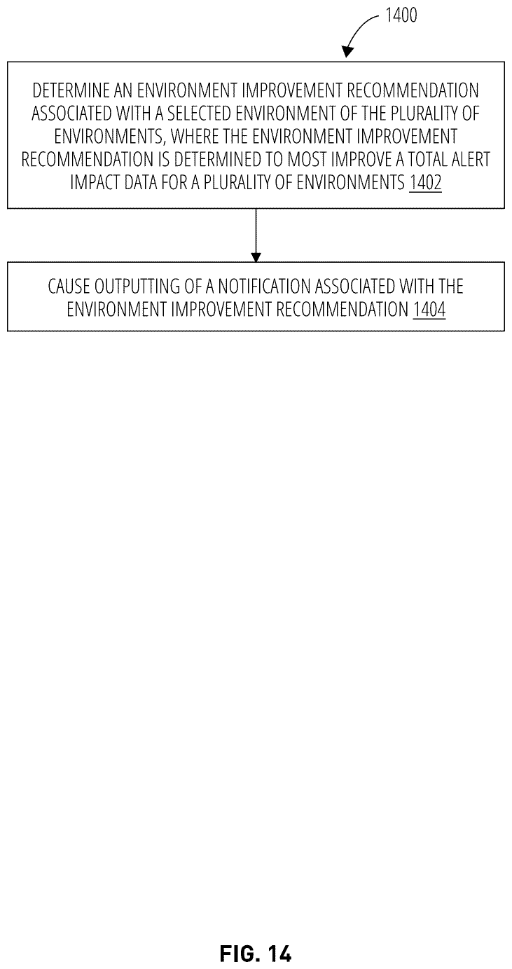

FIG. 14 illustrates an example process 1400 for determining and outputting an environment improvement recommendation for improving total alert impact data for an environment portfolio in accordance with at least some embodiments of the present disclosure. Specifically, FIG. 14 depicts an example process 1400 for determining a portfolio-level environment improvement recommendation, for example associated with an environment portfolio including a plurality of environments. In some embodiments, the computer-implemented process 1400 is embodied by computer program code stored on a non-transitory computer-readable medium of a computer program product configured for execution to perform the computer-implemented method. Alternatively or additionally, in some embodiments, the example process 1400 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 1400. In some embodiments, the specially configured apparatus 200 includes and/or otherwise is in communication with one or more external apparatuses, systems, devices, and/or the like, to perform one or more of the operations as depicted and described.

The process 1400 begins at operation 1402. In some embodiments, the process 1400 begins after one or more operations of another process, such as the operation 804 of the process 800 as depicted and described. Additionally or alternatively, in some embodiments, upon completion of the process 1400 flow proceeds to one or more operations of another process. In this regard, some or all of the process 1400 may replace or supplement one or more blocks depicted and/or described with respect to any of the processes described herein. Upon completion of the process 1400, the flow of operations may terminate. It will be appreciated that, in some embodiments, the process 1400 embodies a sub-process of one or more other process(es) depicted and/or described herein, for example the process 800.

At operation 1402, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that determines an environment improvement recommendation associated with a selected environment of the plurality of environments, where the environment improvement recommendation is determined to most improve a total alert impact data for a plurality of environments. In some such embodiments, the plurality of environments are identified as associated with a particular portfolio identifier. In some embodiments, the total alert impact data embodies an aggregation of all alert impact data associated with each environment of the plurality of environments. In one example context, the total alert impact data represents a total deferred maintenance cost associated with all environments of an environment portfolio.

In some embodiments, the apparatus 200 utilizes one or more improvement recommendation model(s) to determine the environment improvement recommendation. In some embodiments, the improvement recommendation model determines which environment improvement recommendation from a set of candidate environment improvement recommendations is determined or predicted to provide the most improvement to the total alert impact data, for example by improving the underlying monitored data value and/or corresponding data insight(s) associated with one or more alert(s) contributing to at least a portion of the total alert impact data. In one example context, alert(s) indicating a system is malfunctioning sporadically in a first environment, for example, may be associated with a lesser contributing alert impact data than second alert impact data associated with alert(s) indicating that the same system in a second environment is entirely broken. It should be appreciated that the environment improvement recommendation determined for the plurality of environments may be associated with a particular selected environment, for example where the environment improvement recommendation represents an action to be performed associated with maintaining the selected environment specifically.

At operation 1404, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that causes outputting of a notification associated with the environment improvement recommendation. For example, the notification may identify the environment improvement recommendation and/or indicate the determined or predicted improvement to the data insight for the selected environment in particular that the environment improvement recommendation provides. Additionally or alternatively, in some embodiments the notification indicates why the determined environment improvement recommendation for the selected environment was selected over alternative candidate environment improvement recommendations. In some embodiments, the notification is outputted to a user device. In some embodiments, the apparatus 200 outputs the notification as part of a user interface including environment value data, alert impact data, and/or the like. Alternatively or additionally, in some embodiments the apparatus 200 outputs the notification as a separate transmission, for example to be rendered via a push notification, text message, email, and/or the like. In some embodiments, the user device embodies a client device connected with the apparatus 200 via an authenticated session. In other embodiments, the user device embodies a determinable computing device associated with the environment.

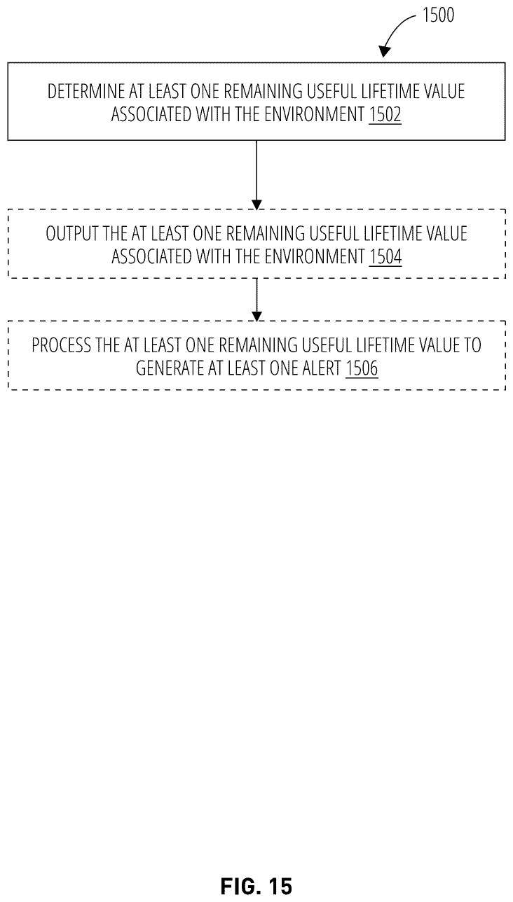

FIG. 15 illustrates an example process 1500 for determining and outputting a remaining useful lifetime of a system impacting operational aspect(s) of an environment in accordance with at least some embodiments of the present disclosure. Specifically, FIG. 15 depicts an example process 1500 for determining a portfolio-level environment improvement recommendation, for example associated with determining and using at least one remaining useful lifetime value associated with an environment. In some embodiments, the computer-implemented process 1500 is embodied by computer program code stored on a non-transitory computer-readable medium of a computer program product configured for execution to perform the computer-implemented method. Alternatively or additionally, in some embodiments, the example process 1500 is performed by one or more specially configured computing devices, such as the data & impact monitoring system 102 embodied by the specially configured apparatus 200. In this regard, in some such embodiments, the apparatus 200 is specially configured by computer program instructions stored thereon, for example in the memory(s) 204 and/or another component depicted and/or described herein, and/or otherwise accessible to the apparatus 200, for performing the operations as depicted and described with respect to the example process 1500. In some embodiments, the specially configured apparatus 200 includes and/or otherwise is in communication with one or more external apparatuses, systems, devices, and/or the like, to perform one or more of the operations as depicted and described.

The process 1500 begins at operation 1502. In some embodiments, the process 1500 begins after one or more operations of another process, such as the operation 804 of the process 800 as depicted and described. Additionally or alternatively, in some embodiments, upon completion of the process 1500 flow proceeds to one or more operations of another process. In this regard, some or all of the process 1500 may replace or supplement one or more blocks depicted and/or described with respect to any of the processes described herein. Upon completion of the process 1500, the flow of operations may terminate. It will be appreciated that, in some embodiments, the process 1500 embodies a sub-process of one or more other process(es) depicted and/or described herein, for example the process 800.

At operation 1502, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that determines at least one remaining useful lifetime value associated with the environment. In one example context, the remaining useful lifetime value represents a determine or predicted time until a system within or otherwise associated with the environment requires replacement and/or maintenance. In some embodiments, the apparatus 200 utilizes one or more algorithmic, statistical, machine learning, and/or artificial intelligence models specially trained to determine the remaining useful lifetime value. Additionally or alternatively, in some embodiments, the apparatus 200 determines the remaining useful lifetime value for one or more system(s) based at least in part on predetermined remaining useful lifetime value(s) for such system(s) and/or a determined timestamp interval since such system(s) were maintained and/or replaced.

At optional operation 1504, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that outputs the at least one remaining useful lifetime value associated with the environment. In some embodiments, the apparatus 200 outputs the at least one remaining useful lifetime value as part of a user interface including environment value data, alert impact data, and/or the like. For example, the remaining useful lifetime value may be outputted as a graph (e.g., depicting a prediction of the rate at which the remaining useful lifetime value of the channel may diminish), one or more data label(s), and/or the like. Alternatively or additionally, in some embodiments, the apparatus 200 outputs data value(s), data insight(s), and/or alert(s) derived from the remaining useful lifetime value.

At optional operation 1506, the apparatus 200 includes means such as the identity management circuitry 210, data management circuitry 212, data modeling circuitry 214, notifying circuitry 216, communications circuitry 208, input/output circuitry 206, and/or processor(s) 202, or a combination thereof, that processes the at least one remaining useful lifetime value to generate at least one alert. For example, in some embodiments, the remaining useful lifetime value for a particular system or set of systems embodies a data insight utilized to generate one or more alert(s). In this regard, the remaining useful lifetime value for a particular system may directly contribute to alert impact data associated with the corresponding environment.

### Example User Interfaces of the Disclosure

Having described example systems, apparatuses, data flows, and processes associated with embodiments of the present disclosure, example user interfaces of the disclosure will now be discussed. The user interfaces may be configured by a particular computing device and/or system, for example the data & impact monitoring system 102 embodied by the apparatus 200 in some embodiments. Alternatively or additionally, in some embodiments the particular computing device and/or system, for example the data & impact monitoring system 102 embodied by the apparatus 200, generates and transmits particular data for use in configuring one or more interface elements of the user interface(s). For example the apparatus 200 may generate and/or transmit data insight(s) associated with particular data metrics utilized in depicting a data value via a label, configuring a graph, map, or other visual element. In some embodiments, the user interface(s) are renderable via a client device, for example the client device(s) 104, in communication with a data & impact monitoring system 102, for example embodied by the apparatus 200) as described herein. Alternatively or additionally, in some embodiments, the user interface(s) are renderable via a display associated with the data & impact monitoring system 102, for example embodied by the apparatus 200.

In some embodiments, the apparatus 200 determines, generates, and/or otherwise identifies the particular data value(s) to be depicted via one or more user interface(s) in any of a myriad of manners. In some embodiments, the apparatus 200 performs the described data collection, gathering, normalization, abstraction, and/or the like to identify the particular data values for depicting via one or more of the user interfaces as described herein. In this regard, the data manipulation operations and/or generation operations described herein in some embodiments enable the apparatus 200 to accurately identify particular data for outputting.

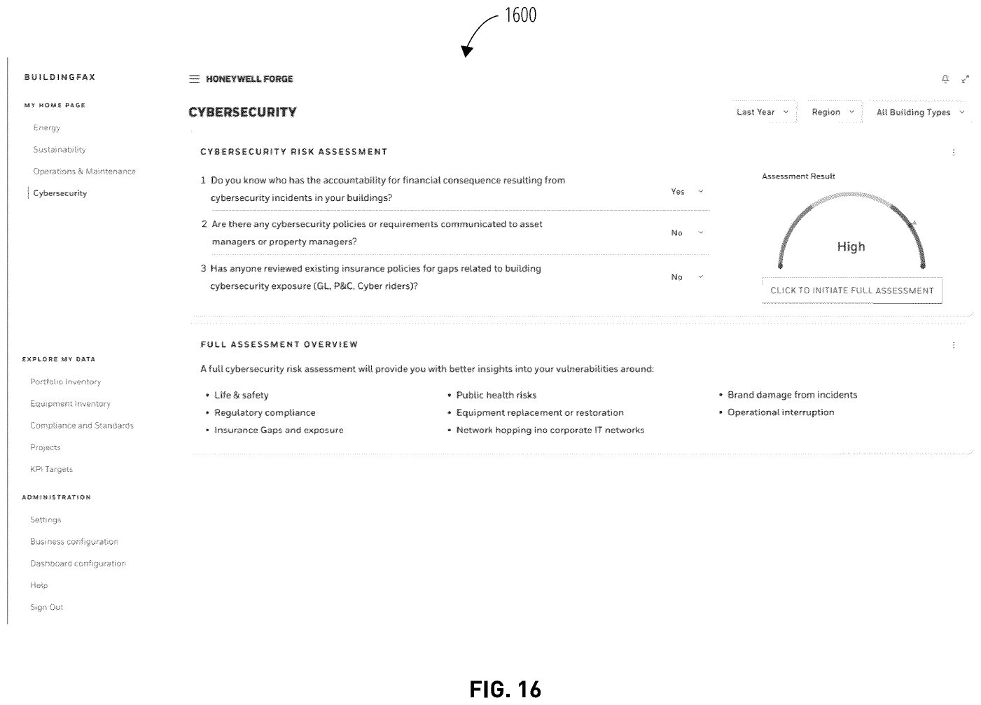

FIG. 16 illustrates an example user interface associated with cybersecurity data insights in accordance with at least some embodiments of the present disclosure. Specifically, FIG. 16 depicts a user interface 1600 that includes various cybersecurity data insights associated with various cybersecurity risk metrics. In some embodiments, one or more of the cybersecurity data insights corresponds to system cybersecurity risk data indicating particular aspects of the cybersecurity risks posed to a particular environment or portfolio of environments.

In some embodiments, the user interface 1600 includes one or more filtering elements. The filtering elements may filter the data depicted via the user interface 1600 in any of a myriad of manners, for example by limiting particular data parameters associated with each data insight. For example, in some embodiments, the user interface 1600 includes a filtering element that configures the user interface 1600 to depict data insights associated with a particular time interval (e.g., selection of a year from a plurality of years for which the particular data insights is available). Additionally or alternatively, in some embodiments the user interface 1600 includes a filtering element that configures the user interface 1600 to depict data insights associated with environment(s) of a particular region. In this regard, such a filtering element may be utilized to select a particular predefined region, user-defined region, or other defined area that encompasses particular locations associated with particular environments. Additionally or alternatively, in some embodiments, the user interface 1600 includes a filtering element that enables selection of an environment type utilized to configures the user interface 1600. In this regard, such a filtering element may be utilized to select a particular environment type such that the selected environment type may be utilized to identify data insights associated with environments corresponding to the particular selected environment type. It should be appreciated that the selected filtering values corresponding to any number of filtering elements may be combined.

In some embodiments, the user interface 1600 includes one or more interface elements for navigating between user interface(s) associated with different data insights. In some embodiments, the user interface 1600 includes a sidebar including a separate user interface element corresponding to each data insight of a plurality of different data insights. For example, in some embodiments, the sidebar includes an interface element associated with a user interface corresponding to energy performance data insights, an interface element associated with a user interface corresponding to sustainability data insights, an interface element associated with a user interface corresponding to operations & maintenance data insights, and an interface element associated with a user interface corresponding to cybersecurity data insights.

Additionally or alternatively, in some embodiments, the user interface 1600 includes one or more interface elements for accessing user interfaces depicting particular data and/or derived data insights associated with a particular environment or portfolio of environments. For example, in some embodiments, the user interface 1600 includes one or more interface elements for accessing data identifying environments in a particular portfolio of environments. Additionally or alternatively, in some embodiments, the user interface 1600 includes one or more interface elements depicting an identification of equipment within an environment or a portfolio of environments, and/or data associated with the equipment. Additionally or alternatively, in some embodiments, the user interface 1600 includes one or more interface elements depicting data associated with standards, regulations, or the like for compliance by an environment or a portfolio of environments, and/or data associated with compliance of the standards, regulations, or the like. Additionally or alternatively, in some embodiments, the user interface 1600 includes one or more interface elements depicting data associated with projects being performed corresponding to an environment or a plurality of environments. Additionally or alternatively, in some embodiments, the user interface 1600 includes one or more interface elements depicting data associated with target data values for one or more data insights associated with particular data metrics (e.g., representing key performance indicators or “KPIs”).

In some embodiments, the user interface 1600 depicts data insights embodying a cybersecurity assessment of one or more environments(s). For example, the cybersecurity assessment may include data insights representing responses to particular cybersecurity inquiries for a particular environment or a portfolio of environments. As illustrated, the user interface 1600 includes a plurality of distinct cybersecurity inquiries with selectable “yes” or “no” response indicators. It will be appreciated that the cybersecurity inquiries may be associated with any of a myriad of cybersecurity-related operations for the building or portfolio of buildings, and a corresponding response data value of any of a myriad of data types (e.g., a Boolean TRUE/FALSE or YES/NO, an integer, a text string response, and/or the like).

In some embodiments, the user interface 1600 depicts a data insight representing a data value for an overall cybersecurity risk metric. In some embodiments, the overall cybersecurity risk metric represents the overall threat of cybersecurity vulnerabilities to operations of a particular environment or portfolio of environments. In some embodiments, the overall cybersecurity risk metric may be associated with a data value from a set of candidate risk levels (e.g., a “high” risk level, a “moderate” risk level, and a “low” risk level). Alternatively or additionally, in some embodiments, the overall cybersecurity risk metric may be associated with a normalized data value within a particular range indicating different levels of cybersecurity risk (e.g., a range from 0.0 to 100.0 inclusive, wherein 0.0 indicates no cybersecurity risk and 100.0 indicates maximum cybersecurity risk). As illustrated, the user interface 1600 depicts the data insight representing the overall cybersecurity risk metric via a graphical user interface element that visually depicts the value of the overall cybersecurity risk metric along a loading bar, color-coded graph, and/or the like.

Additionally or alternatively, in some embodiments, the user interface 1600 includes one or more interface element to initiate a full cybersecurity assessment of an environment or portfolio of environments. For example, in some embodiments, the user interface 1600 includes a button that initiates a full cybersecurity assessment of an environment or portfolio of environments. In some embodiments, the full cybersecurity assessment includes one or more data-driven processes performed by the apparatus 200, or in some embodiments that includes one or more offline-performed processes or processes performed by a separate system, that determine data values for cybersecurity data insight(s).

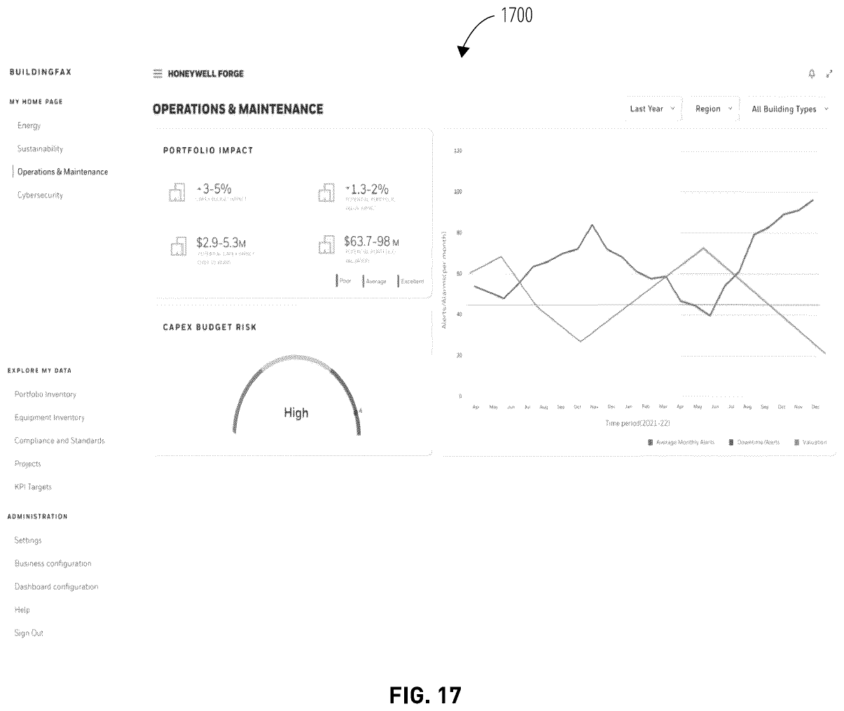

FIG. 17 illustrates an example user interface associated with operations & maintenance data insights in accordance with at least some embodiments of the present disclosure. Specifically, FIG. 17 depicts a user interface 1700 that includes various operations & maintenance data insights associated with various environment operations metrics and/or environment maintenance metrics. In some embodiments, one or more of the operations & maintenance data insights corresponds to environment value data and/or impact data, such as alert impact data, that offsets the environment value data associated with a particular environment or a portfolio of environments.

In some embodiments, the user interface 1700 includes one or more filtering elements. For example, in some embodiments, the user interface 1700 includes the same and/or similar filtering elements as described with respect to FIG. 16. Such elements may filter the data insights depicted via the user interface 1700. For brevity and clarity, repeated description of such filter elements is omitted.

In some embodiments, the user interface 1700 includes one or more interface elements for navigating between user interface(s) associated with different data insights. For example, in some embodiments, the user interface 1700 includes a sidebar including a separate user interface element corresponding to each data insight of a plurality of different data insights. In some embodiments, the sidebar and/or particular interface elements for navigating between user interface(s) includes the same and/or similar interface elements as described with respect to FIG. 16. For brevity and clarity, repeated description of such navigation elements is omitted.

In some embodiments, the user interface 1700 includes one or more interface elements for accessing user interfaces depicting particular data and/or derived data insights associated with a particular environment or portfolio of environments. In some embodiments, the interface element(s) for navigating to user interface(s) depicting such data and/or derived data insight(s) includes the same and/or similar interface elements as described with respect to FIG. 16. For brevity and clarity, repeated description of such navigation elements is omitted.

In some embodiments, the user interface 1700 depicts operations & maintenance data insights corresponding to environment operations metrics and/or environment maintenance metrics, for example representing impact data associated with a portfolio of environments. In some embodiments, the data insights include portfolio-level impact data derived from or otherwise aggregated based at least in part on impact data for one or more environments associated with the portfolio of environments. In some embodiments, the impact data includes or embodies alert impact data derived based at least in part on alert(s) for each environment associated with a portfolio of environments. For example, as illustrated, the user interface 1700 includes a data value representing a portfolio-level impact data (e.g., an estimated range of potential portfolio value impact, for example representing a percentage impact on a portfolio-level environment value data attributable to deferred maintenance of environments), a data value representing portfolio-level environment value data (e.g., an estimated range of a value for a portfolio of environments, including based on current offsets for deferred maintenance and/or the like), a projected portfolio-level impact data for a particular timestamp interval (e.g., an estimated range of potential portfolio value impact, for example representing a currency cost attributable to deferred maintenance of environments over 10 years), and/or budget portfolio-level impact data (e.g., representing an estimated range of increase in budgeted currency if deferred maintenance is further stalled). It will be appreciated that any of a number of data-driven determinations, data insights, and/or the like may be determined based at least in part on a combination of data values associated with a particular environment or portfolio of environments, for example budget data, impact data, environment value data, and/or the like.

In some embodiments, the user interface 1700 depicts a data insight embodying an overall portfolio-level of risk posed by such particular operations & maintenance data insights. In some embodiments, the overall portfolio-level of risk posed by such particular operations & maintenance data insights may be associated with a data value from a set of candidate risk levels (e.g., a “high” risk level, a “moderate” risk level, and a “low” risk level). Alternatively or additionally, in some embodiments, the overall portfolio-level of risk posed by such particular operations & maintenance data insights may be associated with a normalized data value within a particular range indicating different levels of overall risk posed by such operations & maintenance data insights (e.g., a range from 0.0 to 100.0 inclusive, wherein 0.0 indicates no operations & maintenance data insight risk and 100.0 indicates maximum operations & maintenance data insight risk). As illustrated, the user interface 1700 depicts the data insight representing the overall portfolio-level of risk posed by such particular operations & maintenance data insights via a graphical user interface element that visually depicts the value along a loading bar, color-coded graph, and/or the like.

Additionally or alternatively, in some embodiments, the user interface 1700 includes one or more interface element that graphically depicts data insights associated with alert(s) for a particular environment or portfolio of environments. For example, in some embodiments, the user interface 1700 includes a graphical representation of the number of alerts received for all environments of a portfolio of environments within a particular timestamp interval (e.g., a predetermined period or user-selected time interval). In some embodiments, the user interface 1700 comprises a line graph depicting the number of alerts over time. Additionally or alternatively, in some embodiments, the graphical representation includes one or more other data insights. For example, in some embodiments, the graphical representation includes an average monthly alerts line, a downtime/alerts line, and/or an environment valuation data line in the same graphical representation or distinct graphical representations. In some embodiments, the alerts numbered in the graphical representation are similarly utilized to derive the impact data (e.g., embodied by alert impact data) for a particular environment or portfolio of environments.

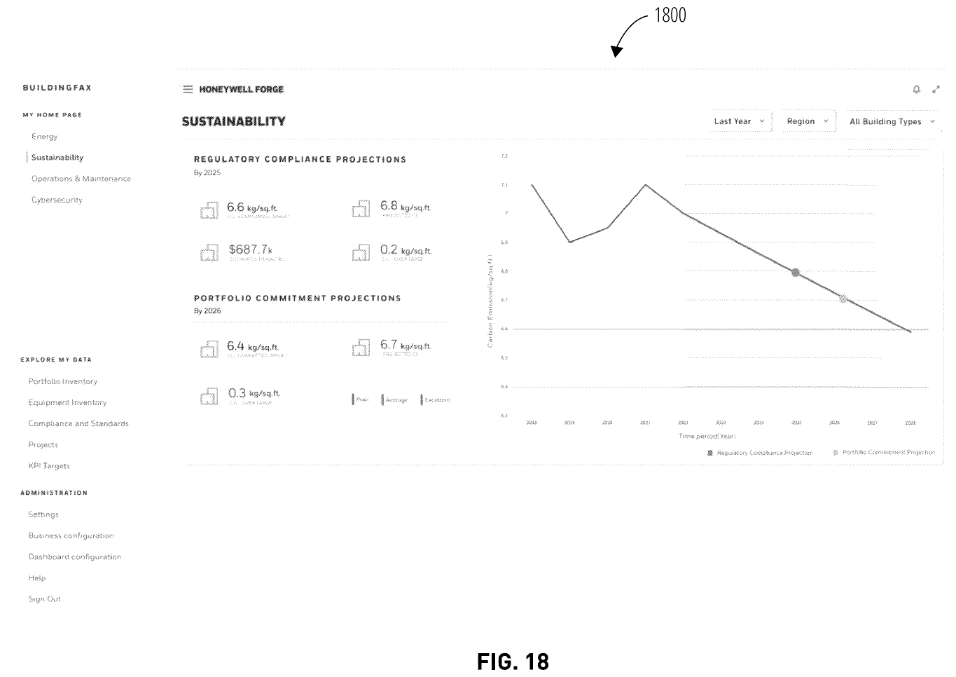

FIG. 18 illustrates an example user interface associated with sustainability data insights in accordance with at least some embodiments of the present disclosure. Specifically, FIG. 18 depicts a user interface 1800 that includes various sustainability data insights associated with various sustainability metrics. In some embodiments, one or more of the sustainability data insights corresponds to data indicating target sustainability metrics, for example determinable based on one or more regulations, rules, and/or the like, and/or projected sustainability metrics, and/or data insights derived therefrom.

In some embodiments, the user interface 1800 includes one or more filtering elements. For example, in some embodiments, the user interface 1800 includes the same and/or similar filtering elements as described with respect to FIG. 16. Such elements may filter the data insights depicted via the user interface 1800. For brevity and clarity, repeated description of such filter elements is omitted.

In some embodiments, the user interface 1800 includes one or more interface elements for navigating between user interface(s) associated with different data insights. For example, in some embodiments, the user interface 1800 includes a sidebar including a separate user interface element corresponding to each data insight of a plurality of different data insights. In some embodiments, the sidebar and/or particular interface elements for navigating between user interface(s) includes the same and/or similar interface elements as described with respect to FIG. 16. For brevity and clarity, repeated description of such navigation elements is omitted.

In some embodiments, the user interface 1800 includes one or more interface elements for accessing user interfaces depicting particular data and/or derived data insights associated with a particular environment or portfolio of environments. In some embodiments, the interface element(s) for navigating to user interface(s) depicting such data and/or derived data insight(s) includes the same and/or similar interface elements as described with respect to FIG. 16. For brevity and clarity, repeated description of such navigation elements is omitted.

In some embodiments, the user interface 1800 depicts sustainability data insights corresponding to operations of an environment or portfolio of environments. For example, the sustainability data insights may embody target data values for a particular measurable metric, projected data values for a particular measurable metric, a current value for a particular measurable metric, and/or impact data associated with environment value data based on the relationship between the target and current and/or projected data values for the metric. Such measurable metrics associated with sustainability data insights may include carbon dioxide emissions, energy usage, pollution emissions, and/or the like. As illustrated, the user interface 1800 includes a sustainability data insight embodying a compliance target for carbon dioxide emissions (e.g., defined by legal regulations for example) at two timestamps (2025 and 2026). The user interface 1800 further includes a sustainability data insight embodying a projected carbon dioxide emissions for a particular environment or portfolio of environments at the two timestamps. The user interface 1800 further includes a sustainability data insight embodying a derived value that the projected value is over the target value (e.g., based on the difference between the projected value and the target value) at the two timestamps. The user interface 1800 further includes a sustainability data insight embodying impact data representing an estimate of penalties (e.g., fees of a particular currency) that will be owed in circumstances where the target data value is not reached (e.g., penalties defined by a particular regulatory framework).

Additionally or alternatively, in some embodiments, the user interface 1800 includes one or more interface element that graphically depicts one or more sustainability data insight(s) for a particular environment or portfolio of environments. For example, in some embodiments, the user interface 1800 includes a graphical representation of the projected data insight for a particular data metric (e.g., carbon dioxide emissions) for all environments of a portfolio of environments within a particular timestamp interval (e.g., a historical and/or future timestamp interval, or a combination thereof). In some embodiments, the user interface 1800 comprises a line graph depicting the data insight over time. Additionally or alternatively, in some embodiments, the graphical representation includes one or more other data insights. For example, in some embodiments, the graphical representation includes an indicator of the target data value for a particular metric at a particular timestamp on the line graph, and/or particular levels to be reached at particular timestamps of the line graph, in the same graphical representation or distinct graphical representations.

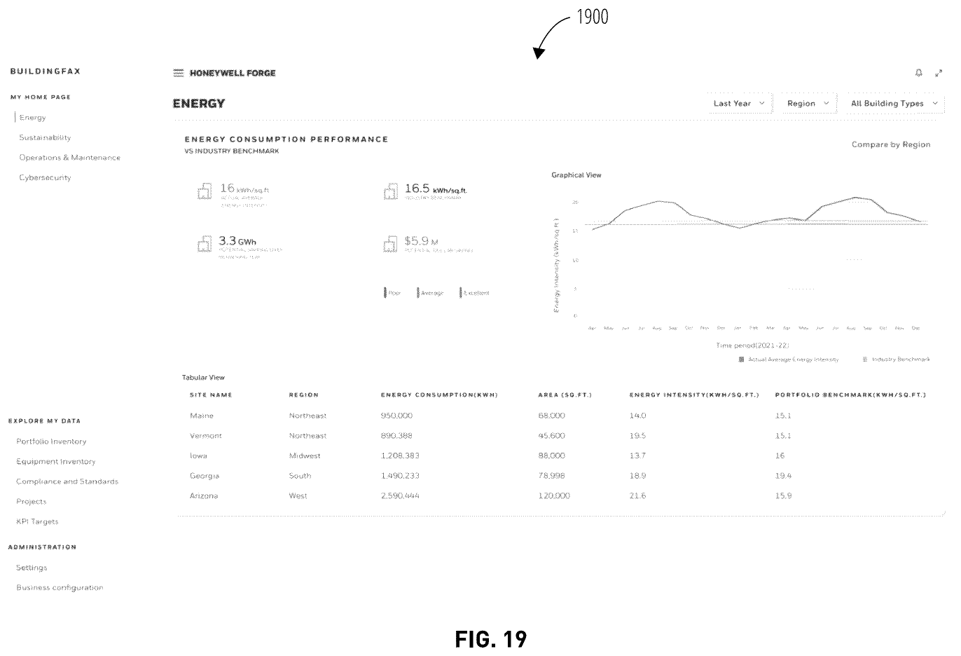

FIG. 19 illustrates an example user interface associated with energy performance data insights in accordance with at least some embodiments of the present disclosure. Specifically, FIG. 19 depicts a user interface 1900 that includes various energy performance data insights associated with various energy performance metrics. In some embodiments, one or more of the energy performance data insights corresponds to data indicating target energy usage metrics, projected and/or determined energy usage metrics, and/or data insights derived therefrom.

In some embodiments, the user interface 1900 includes one or more filtering elements. For example, in some embodiments, the user interface 1900 includes the same and/or similar filtering elements as described with respect to FIG. 16. Such elements may filter the data insights depicted via the user interface 1900. For brevity and clarity, repeated description of such filter elements is omitted.

In some embodiments, the user interface 1900 includes one or more interface elements for navigating between user interface(s) associated with different data insights. For example, in some embodiments, the user interface 1900 includes a sidebar including a separate user interface element corresponding to each data insight of a plurality of different data insights. In some embodiments, the sidebar and/or particular interface elements for navigating between user interface(s) includes the same and/or similar interface elements as described with respect to FIG. 16. For brevity and clarity, repeated description of such navigation elements is omitted.

In some embodiments, the user interface 1900 includes one or more interface elements for accessing user interfaces depicting particular data and/or derived data insights associated with a particular environment or portfolio of environments. In some embodiments, the interface element(s) for navigating to user interface(s) depicting such data and/or derived data insight(s) includes the same and/or similar interface elements as described with respect to FIG. 16. For brevity and clarity, repeated description of such navigation elements is omitted.

In some embodiments, the user interface 1900 depicts energy performance data insights corresponding to energy usage, energy performance data insights, associated with an environment or a portfolio of environments. For example, the energy performance data insights may embody current energy usage values and/or projected energy usage values for an environment or portfolio of environments, a comparable energy usage value (e.g., a benchmark energy performance data insight for an energy usage metric), potential energy savings as compared to a particular benchmark for a particular time interval, and/or a projected impact data associated with environment value data based on the potential energy savings.

Additionally or alternatively, in some embodiments, the user interface 1900 includes one or more interface elements that arrange data insights associated with a particular environment, portfolio of environments, or sub-groupings of a portfolio of environments. For example, in some embodiments, data insights associated with each environment of a portfolio of environments is arranged into a table representation. In some embodiments, the table representation depicts each environment identifier, environment region, environment area, environment energy performance data insight corresponding to an energy used metric, and a portfolio benchmark for the energy performance data insight. The table representation may arrange such data in a manner that is sortable, filterable, and/or otherwise manipulable for efficient analysis by a user.

Additionally or alternatively, in some embodiments, the user interface 1900 includes one or more interface elements that graphically depicts one or more energy performance data insight(s) for a particular environment or portfolio environments. For example, in some embodiments, the user interface 1900 includes a graphical representation of the energy performance data insights representing an energy data usage over a time interval. For example, in some embodiments, the user interface 1900 comprises a line graph depicting the energy usage for a portfolio of environments at various timestamps over a particular time interval. Additionally or alternatively, in some embodiments, the graphical representation includes one or more other energy performance data insights. For example, in some embodiments, the graphical representation includes data indicating an average energy usage data insight across a time interval, and/or a benchmark energy usage data insight, in the same graphical representation or distinct graphical representations.

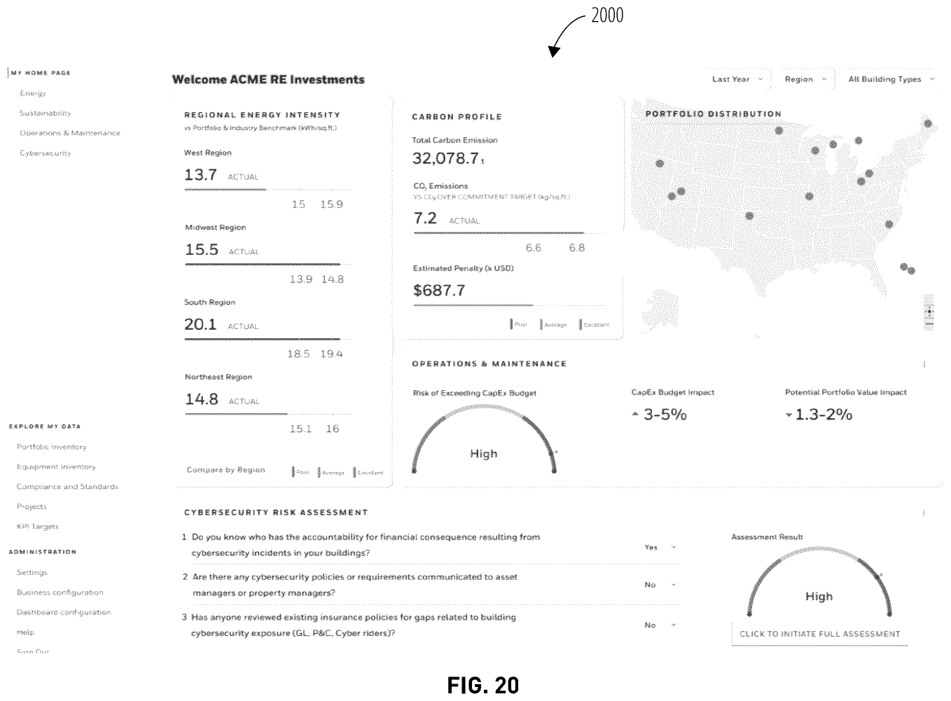

FIG. 20 illustrates an example user interface associated with portfolio-level data insights for a plurality of different types of data insights in accordance with at least some embodiments of the present disclosure. Specifically, FIG. 20 depicts a user interface 2000 that represents a dashboard of various types of data insights associated with a portfolio of environments. In some embodiments, the various types of data insights correspond to one or more of the types of data insights discussed with respect to FIGS. 16-19 and/or otherwise herein.

In some embodiments, the user interface 2000 includes one or more filtering elements. For example, in some embodiments, the user interface 2000 includes the same and/or similar filtering elements as described with respect to FIG. 16. Such elements may filter the data insights depicted via the user interface 2000. For brevity and clarity, repeated description of such filter elements is omitted.

In some embodiments, the user interface 2000 includes one or more interface elements for navigating between user interface(s) associated with different data insights. For example, in some embodiments, the user interface 2000 includes a sidebar including a separate user interface element corresponding to each data insight of a plurality of different data insights. In some embodiments, the sidebar and/or particular interface elements for navigating between user interface(s) includes the same and/or similar interface elements as described with respect to FIG. 16. For brevity and clarity, repeated description of such navigation elements is omitted.

In some embodiments, the user interface 2000 includes one or more interface elements for accessing user interfaces depicting particular data and/or derived data insights associated with a particular environment or portfolio of environments. In some embodiments, the interface element(s) for navigating to user interface(s) depicting such data and/or derived data insight(s) includes the same and/or similar interface elements as described with respect to FIG. 16. For brevity and clarity, repeated description of such navigation elements is omitted.

In some embodiments, the user interface 2000 depicts a map indicating each location of an environment associated with a particular portfolio of environments. For example, in some embodiments, the map includes a visual indicator in the map at each location corresponding to each particular environment. In this regard, the map may be utilized to visually determine—in an efficient manner—where each environment is located.

In some embodiments, the user interface 2000 depicts sub-interfaces corresponding to each of cybersecurity data insights, operations & maintenance data insights, sustainability data insights, energy performance data insights, and/or the like. In some embodiments, one or more of the sub-interfaces includes data insights separated by sub-groupings of a portfolio of environments. For example, in some embodiments, a sub-interface associated with energy performance data insights is separated by sub-groupings of a portfolio of environments corresponding to geographical regions assigned to or determined for particular environments (e.g., from a predetermined candidate set of regions). In this regard, the user interface 2000 may embody a dashboard that depicts a particular portion of each type of data insights. In some embodiments, the particular data insights depicted via the user interface 2000 for a particular data insight type are predetermined. Alternative or additionally, in some embodiments, the particular data insights depicted via the user interface 2000 for a particular data insight type are configurable by a user, such that the user may select particular data insights to depict and/or particular interface elements utilized to depict such data insights.

In some embodiments, the user interface 2000 depicts energy performance data insights corresponding to energy usage, energy performance data insights, associated with an environment or a portfolio of environments. For example, the energy performance data insights may embody current energy usage values and/or projected energy usage values for an environment or portfolio of environments, a comparable energy usage value (e.g., a benchmark energy performance data insight for an energy usage metric), potential energy savings as compared to a particular benchmark for a particular time interval, and/or a projected impact data associated with environment value data based on the potential energy savings.

Additionally or alternatively, in some embodiments, the user interface 2000 includes one or more interface elements that arrange data insights associated with a particular environment, portfolio of environments, or sub-groupings of a portfolio of environments. For example, in some embodiments, data insights associated with each environment of a portfolio of environments is arranged into a table representation. In some embodiments, the table representation depicts each environment identifier, environment region, environment area, environment energy performance data insight corresponding to an energy used metric, and a portfolio benchmark for the energy performance data insight. The table representation may arrange such data in a manner that is sortable, filterable, and/or otherwise manipulable for efficient analysis by a user.

Additionally or alternatively, in some embodiments, the user interface 2000 includes one or more interface elements that graphically depicts one or more energy performance data insight(s) for a particular environment or portfolio environments. For example, in some embodiments, the user interface 2000 includes a graphical representation of the energy performance data insights representing an energy data usage over a time interval. For example, in some embodiments, the user interface 2000 comprises a line graph depicting the energy usage for a portfolio of environments at various timestamps over a particular time interval. Additionally or alternatively, in some embodiments, the graphical representation includes one or more other energy performance data insights. For example, in some embodiments, the graphical representation includes data indicating an average energy usage data insight across a time interval, and/or a benchmark energy usage data insight, in the same graphical representation or distinct graphical representations.

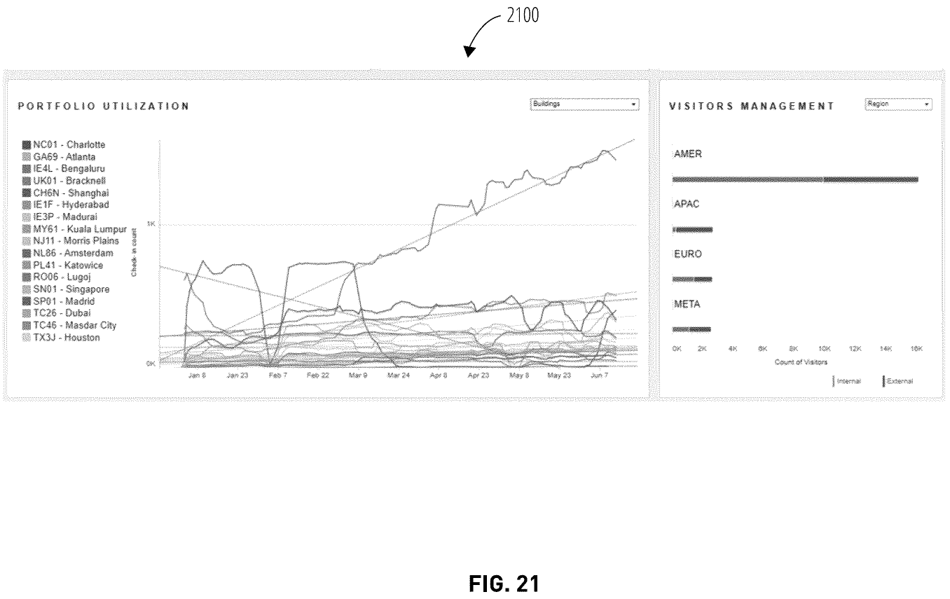

FIG. 21 illustrates an example sub-interface depicting portfolio utilization based on visitor count in accordance with at least some embodiments of the present disclosure. Specifically, FIG. 21 illustrates an example user interface 2100. In some embodiments, the user interface 2100 is rendered as a standalone interface to a particular display. Alternatively or additionally, in some embodiments, the user interface 2100 is renderable as a sub-interface within another user interface, dashboard, and/or the like. For example, in some embodiments, the user interface 2100 is rendered as a sub-interface of the user interface 2000 as depicted and described herein.

The user interface 2100 includes various visitor data insights associated with particular visitation metrics, for example. In this regard, a visitation metric may track how many visitors physically enter a particular environment, for example a particular building. A visitor in some embodiments includes all people that physically enter an environment, and/or particular subsets thereof (e.g., where employees are not counted, for example). Monitored data associated with the visitation metric in some embodiments includes data tracked via one or more sensor(s), scanner(s), and/or the like, that detect or authorize each entrant to a particular environment. In other embodiments, the monitored data for a particular environment is based at least in part on user-submitted or other offline tracked visitation data.

In some embodiments the user interface 2100 depicts visitor data insights in one or more textual and/or graphical formats. As illustrated, the user interface 2100 includes visitor data insights as a line graph, with each line corresponding to a different environment. In this regard, the line graph may depict values of visitor data insights over a particular timestamp interval, which in some embodiments is configurable by an end user interacting with the user interface 2100. Additionally or alternatively, in some embodiments, the user interface 2100 includes trendlines, averages, and/or other derived trends associated with different environments. In some embodiments, the graphical visualization is filterable, sortable, and/or otherwise manipulable by an end user to define the timestamp interval, the environments that are depicted via the graphical visualization (e.g., based at least in part on a region identifier, a sub-region identifier, and/or the like). In this regard, the graphical visualization in some embodiments provides an intuitive interpretation of the visitor insight data corresponding to particular visitation metric(s).

Additionally or alternatively, in some embodiments, the user interface 2100 includes interface elements depicting individual visitor data insight(s), aggregation(s) of visitor data insight(s), and/or other derivation(s) and/or combination(s) of individual data insight(s). As illustrated, the user interface 2100 includes a bar graph representation of visitor insight data aggregated for environments associated with different region identifiers (e.g., “AMER” identifier representing Americas environments tagged as such, “APAC” representing Asia-Pacific, “EURO” representing European, and “META” representing Middle East, Turkey, and Africa). The bar graph representation may depict individual visitor insight data values, for example representing a number of visitors over a particular timestamp interval, as different sub-portions of the bar in different colors, such that the complete bar represents the visitor insight data for all environments aggregated together. It will be appreciated that environments are aggregable in any of a myriad of manners, for example based on environment size, age of ownership, sub-region (e.g., by state, country, and/or the like), or by any other automatically-determined or user-defined metric.

In some embodiments, the apparatus 200 determines recommendation(s) associated with one or more data insight(s). The recommendation(s) in some embodiments represents changes to an environment, and/or use of particular external tool(s), software application(s), and/or the like that impact management of and/or control of an environment, to improve one or more data insight(s). In some embodiments, the apparatus 200 determines recommendation(s) based at least in part on a pre-defined relationship with the recommendation, for example depicting a particular recommendation associated with each type of data insight and/or selecting from a pre-defined list of recommendation options. In some embodiments, each recommendation represents a software service that may be purchased, accessed, or otherwise offered to the user.

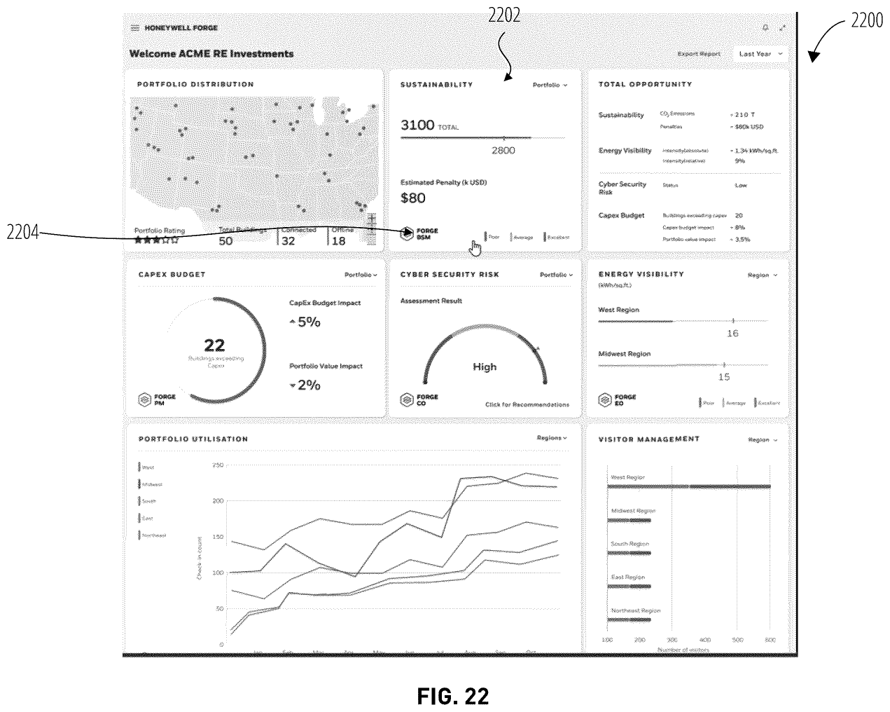

FIG. 22 illustrates an example user interface associated with portfolio-level data insight adjustable based on predicted data impacts of proposed recommendations in accordance with at least some embodiments of the present disclosure. Specifically, FIG. 22 illustrates an example user interface 2200 that represents a dashboard of various types of data insights associated with a possible recommendation corresponding to such data insight(s) for different metric(s). For example, FIG. 22 includes a sub-interface corresponding to an energy performance metric, a sustainability metric, a cybersecurity risk metric, a value impact metric, a visitation metric, and/or the like.

As illustrated, the user interface 2200 includes a first sub-interface 2202 corresponding to sustainability metrics. The sub-interface 2202 depicts visualizations of sustainability data insights associated with such sustainability metrics, including a first data insight representing a total energy usage for one or more environments of a particular environment portfolio (or other grouping, for example based on region), and a second insight representing an estimated penalty cost associated with the energy usage based at least in part on a permissible total energy usage (e.g., based on a regulation limit). It will be appreciated that the data insights may be derivable by particular monitored data associated with each of the environments in the environment portfolio.

The sub-interface 2202 further includes a recommendation toggle interface element 2204. The recommendation toggle interface element 2204 in some embodiments is configured to receive user engagement. Upon user engagement, the sub-interface 2202 may be updated to depict predicted data impact(s) on the data insights provided via use of a recommendation.

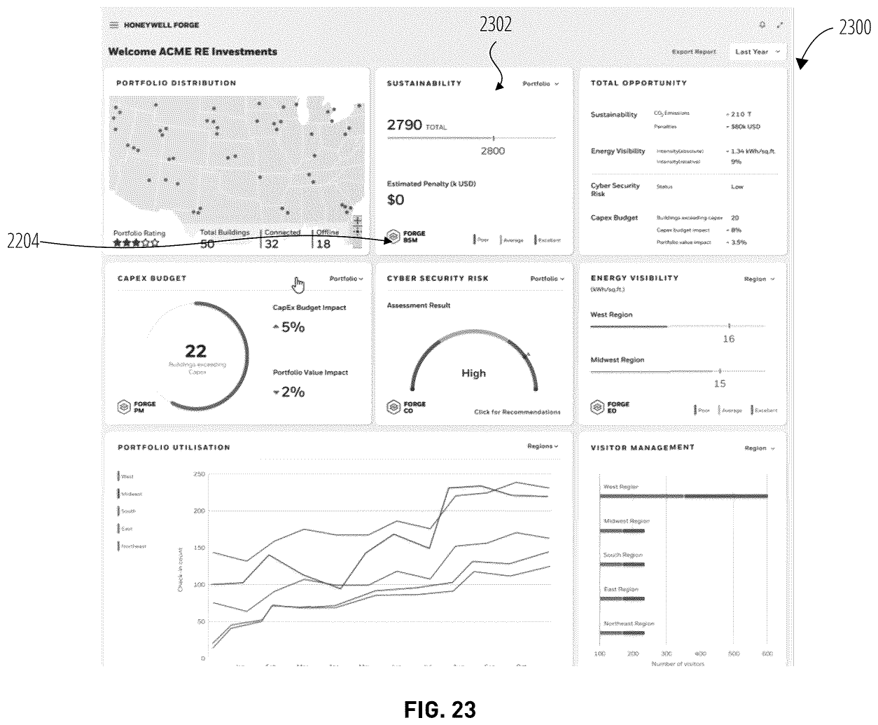

FIG. 23 illustrates an example user interface associated with portfolio-level data insights after adjustment based on predicted data impacts of proposed recommendations in accordance with at least some embodiments of the present disclosure. FIG. 23 illustrates an example user interface 2300 that represents a dashboard with at least one adjusted data insight based at least in part on a recommendation. Specifically, user interface 2300 depicts the user interface 2200 having an updated sub-interface 2302 associated with sustainability metrics. In some embodiments, the user interface 2200 is updated dynamically to depict the sub-interface 2302 upon engagement with the recommendation toggle interface element 2204.

In some embodiments, the apparatus 200 determines adjusted data insights based at least in part on a recommendation. For example, in some embodiments, a recommendation is associated with particular impact data to one or more data insight(s). A recommendation of a particular application associated with sustainability metrics may be utilized or provide instructions to reduce total energy utilization in one or more environments of the environment portfolio.

In some embodiments, a recommendation is associated with particular data impact(s) for one or more corresponding metrics and/or data insights. For example, in some embodiments, a recommendation is associated with particular data impact(s) determinable based at least in part on changes in data insights for one or more particular data metric(s) by other environments that similarly utilized the recommendation. In some embodiments, changes in data insight(s) are tracked based at least in part on characteristics of the environments, such that environments having similar characteristics (e.g., similar size, similar age, similar uses, and/or the like) may be utilized to derive accurate predicted data impact(s) for a particular environment with such characteristics. Alternatively or additionally, in some embodiments, the data impact for a particular data insight and/or metric is determinable utilizing one or more algorithmic, statistical, and/or machine learning model(s). Alternatively or additionally still, in some embodiments, the data impact is received via communication with the recommendation, for example where the recommendation performs a prediction of the data impact based at least in part on one or more characteristics and/or current data insight(s) for an environment or environment portfolio.

As illustrated in FIG. 23, for example, the sub-interface 2302 is adjusted to depict predicted data insight(s) associated with a particular recommendation. The sub-interface includes a first predicted data insight representing a predicted total energy usage for the one or more environments of the particular environment portfolio upon implementation or use of the recommendation. As illustrated, the recommendation is associated with a predicted decrease in total energy use of 310 (e.g., 310 T of CO2 emission). Additionally, the sub-interface 2302 includes a second predicted data insight representing an estimated penalty cost associated with the predicted total energy usage of $0, decreasing the penalty by 80 (e.g., 80 thousand USD in penalties reduced).

In this regard, it will be appreciated that a user may utilize the user interface, and specifically with recommendation toggle interface elements therein, to toggle between depicting current data insights for particular metrics and predicted data insights for such metrics in real-time. A user may determine which recommendations to utilize, access, purchase, and/or otherwise engage with based at least in part on the data impacts between the current data insights and predicted data insights based on implementation of the recommendation(s). For example, as illustrated, each sub-interface associated with different types of metrics (e.g., sustainability metrics, cyber security risk metrics, and the like) may each be associated with different recommendations, have independently functioning recommendation toggle interface elements, and be utilized to separately visualize the effects of recommendations on each of such metrics.

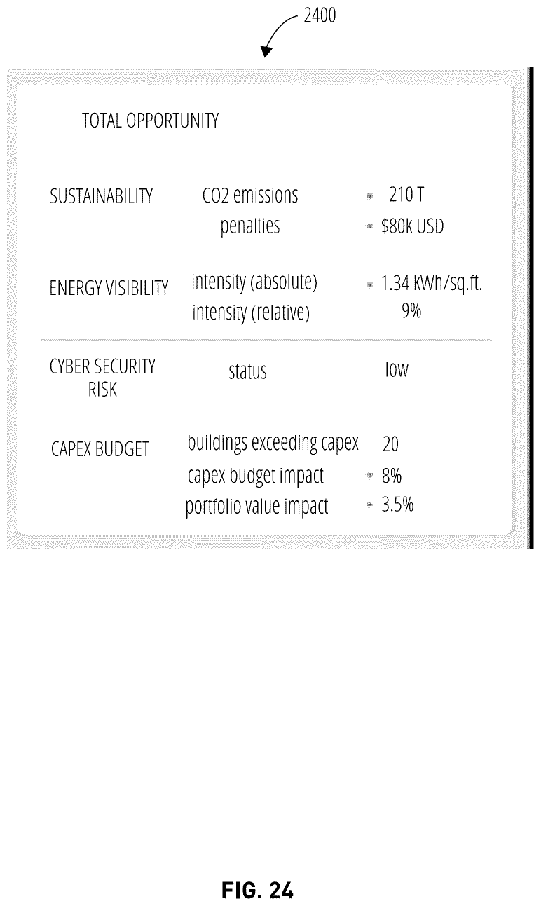

FIG. 24 illustrates an example sub-interface depicting a summary of predicted data impacts of proposed recommendations in accordance with at least some embodiments of the present disclosure. Specifically, FIG. 24 illustrates an example user interface 2400. The user interface 2400 may be rendered as a standalone interface, or in some embodiments as a sub-interface of a dashboard or other user interface. For example, in some embodiments, the user interface 2400 embodies a sub-interface of the user interface 2000 and/or 2200 as depicted and described herein.

The user interface 2400 depicts a summary of data impact(s) of recommendations on various metrics. For example, in some embodiments, the user interface 2400 depicts data impacts representing predicted or otherwise determined changes in such data insights for such metrics that are provided based upon implementation of the recommendations. As illustrated, the user interface 2400 includes data impacts representing predicted changes in data insights for sustainability metrics (e.g., predicted changes in CO2 emissions representing a decrease of 210 T and predicted decrease in penalties of $80 k USD), predicted changes in data insights for energy usage metrics (e.g., predicted changes in energy usage of 1.34 kWh/square foot and relative decrease of 9% for the environment or environment portfolio), data impacts for cyber security risk metrics (e.g., a predicted change in status to low risk), and data impacts for environment value metrics (e.g., a predicted change in environment value data representing a portfolio value impact of an increase of 3.5%, a predicted change in capex budget of a decrease of 8%, and a reduction in environments exceeding an allotted budget of 20). In this regard, the user interface 2400 depicts a predicted impact data for data metrics corresponding to each of such metrics. In some embodiments, the data impacts to one or more data insights is determined based at least in part on predicted data impacts to a plurality of sub-metrics associated with a particular metric.

### CONCLUSION

Although an example processing system has been described above, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results.

What is claimed is:

1. A computer-implemented method comprising:
receiving at least one alert associated with operation of an environment, the at least one alert determined based at least in part on real-time monitored data captured via at least one system in the environment;
applying the at least one alert to a model that determines alert impact data based at least in part on the at least one alert;
determining environment value data based at least in part on the alert impact data; and
outputting at least the environment value data.

2. The computer-implemented method of claim 1, the computer-implemented method further comprising:
receiving an indication of a view type; and
customizing a user interface comprising the environment value data based at least in part on the view type,
wherein outputting at least the environment value data comprises causing rendering of the user interface.

3. The computer-implemented method of claim 1, the computer-implemented method further comprising:
for each alert of the at least one alert, identifying alert importance data corresponding to the alert, the alert importance data comprising at least one of an alert type, a system type, and/or an alert criticality level; and
applying the alert importance data to the model.

4. The computer-implemented method of claim 1, wherein at least a first alert of the at least one alert is associated with an alert criticality level based at least in part on a system type corresponding to the first alert, and/or a location of an environment corresponding to the environment, an alert type corresponding to the alert.

5. The computer-implemented method of claim 1, wherein each alert of the at least one alerts are associated with an alert criticality level selected from a group comprising a low criticality level, a moderate criticality level, a high criticality level, and a critical criticality level, and wherein the alert criticality level for each alert is associated with a different level of impact on the alert impact data.

6. The computer-implemented method of claim 1, the computer-implemented method further comprising:
identifying an environment improvement recommendation determined associated with a contribution to the alert impact data that exceeds a threshold; and
causing outputting of a notification associated with the environment improvement recommendation to a user device.

7. The computer-implemented method of claim 1, the computer-implemented method further comprising:
receiving monitored data associated with the environment;
determining at least one data insight based at least in part on the monitored data;
determining that the at least one data insight does not satisfy a target improvement rate;
identifying an environment improvement recommendation determined to improve the at least one data insight to satisfy the target improvement rate; and
causing outputting of a notification associated with the environment improvement recommendation.

8. The computer-implemented method of claim 7, the computer-implemented method further comprising:
identifying at least a first system associated with the environment that is predicted to most impact the at least one data insight,
wherein the environment improvement recommendation indicates a recommendation of maintenance or replacement of the first system.

9. The computer-implemented method of claim 1, further including:
receiving the real-time monitored data captured via the at least one system; and
generating the at least one alert based at least in part on the real-time monitored data.

10. The computer-implemented method of claim 9, wherein the real-time monitored data includes system cybersecurity risk data.

11. The computer-implemented method of claim 1, the computer-implemented method further comprising:
deriving, based at least in part on the real-time monitored data, at least one score corresponding to at least one metric associated with the environment; and
outputting the at least one score associated with at least one metric.

12. The computer-implemented method of claim 1, the computer-implemented method further comprising:
receiving the real-time monitored data captured via the at least one system;
receiving non-real-time monitored data associated with the environment; and
generating at least a first alert based at least in part on the real-time monitored data and the non-real-time monitored data.

13. The computer-implemented method of claim 1, wherein the at least one alert include a first alert associated with a sustainability metric.

14. The computer-implemented method of claim 1, wherein the at least one alert includes a first alert associated with an energy performance metric.

15. The computer-implemented method of claim 1, the computer-implemented method further comprising:
tracking a timeseries of data records associated with one or more metrics, wherein the at least one alert is determined based at least in part on the timeseries of data records associated with the one or more metrics; and
outputting the timeseries of data records associated with the one or more metrics.

16. The computer-implemented method of claim 1, wherein the environment is associated with an environment portfolio comprising a plurality of environments, portfolio of environments, and wherein each environment of the plurality of environments is associated with particular alert impact data, and wherein the computer-implemented method further comprises:
determining an environment improvement recommendation associated with a selected environment of the plurality of environments, wherein the environment improvement recommendation is determined to most improve a total alert impact data for the plurality of environments; and
causing outputting of a notification associated with the environment improvement recommendation.

17. The computer-implemented method of claim 16, wherein determining the environment improvement recommendation is based at least in part on a constrained resource value.

18. The computer-implemented method of claim 1, wherein the at least one alert is based at least in part on historic data and predicted data associated with the environment, the historic data and the predicted data associated with at least one of a performance metric of the environment, a compliance metric of the environment, and an occupant experience metric of the environment.

19. The computer-implemented method of claim 1, the computer-implemented method further comprising:
determining at least one remaining useful lifetime value associated with the environment; and
outputting the at least one remaining useful lifetime value associated with the environment.

20. A apparatus comprising:
at least one processor; and
at least one memory storing instructions that, when executed by the at least one processor, causes the apparatus to:
receive at least one alert associated with operation of an environment, the at least one alert determined based at least in part on real-time monitored data captured via at least one system in the environment;
apply the at least one alert to a model that determines alert impact data based at least in part on the at least one alert;
determine environment value data based at least in part on the alert impact data; and
output at least the environment value data.

21. A non-transitory computer-readable storage medium, the non-transitory computer-readable storage medium including instructions that when executed by at least one processor, configures the at least one processor to:
receive at least one alert associated with operation of an environment, the at least one alert determined based at least in part on real-time monitored data captured via at least one system in the environment;
apply the at least one alert to a model that determines alert impact data based at least in part on the at least one alert;
determine environment value data based at least in part on the alert impact data; and
output at least the environment value data.
